(19) United States
(12) Patent Application Publication
(10) Pub. No.: US 2026/0280755 A1
(43) Pub. Date: Sep. 17, 2026

(54) METHODS AND APPARATUS FOR ERROR CORRECTION CODING WITH TRANSMISSION DIVERSITY

(71) Applicant: Polaran Haberlesme Teknolojileri Anonim Sirketi, Cankaya (TR)

(72) Inventor: Erdal ARIKAN, Ankara (TR)

(21) Appl. No.: 19/076,859

(22) Filed: Mar. 11, 2025

(51) Int. Cl. H04L 1/00

(52) U.S. Cl. CPC H04L 1/0057

(57) ABSTRACT

The disclosure relates to a 5G or 6G communication system for supporting a higher data transmission rate. The present disclosure discloses a method and an apparatus for error correction coding in a communication system, more specifically, to error correction coding with transmission diversity.

### TECHNICAL FIELD

The present disclosure is directed generally to error correction coding in a communication system, more specifically, to error correction coding with transmission diversity.

### BACKGROUND

5th generation (5G) mobile communication technologies specify broad frequency bands to provide higher transmission rates and new services, and can be deployed in “Sub 6 GHz” bands such as 3.5 GHZ, and also in “above 6 GHz” bands, which may be referred to as mmWave bands including 28 GHz and 39 GHz. In addition, the implementation of 6th generation 6G mobile communication technologies (e.g., beyond 5G systems) in terahertz frequency bands (e.g., 95 GHz to 3 THz bands) has been proposed in order to achieve transmission rates up to fifty times higher than 5G mobile communication technologies and ultra-low latencies approximately one-tenth of 5G mobile communication technologies.

Since the beginning of the development of 5G mobile communication technologies, to support various services and to satisfy performance requirements related to enhanced mobile broadband (eMBB), ultra-reliable low-latency communications (URLLC), and massive machine-type communications (mMTC), there has been ongoing standardization regarding beamforming and massive multi-input multi-output (MIMO) for mitigating radio-wave path loss and extending radio-wave transmission distances in mmWave, introducing numerologies (e.g., operating multiple subcarrier spacings (SCSs)) for efficiently utilizing mmWave resources and dynamic operation of slot formats, initial access technologies for supporting multi-beam transmission and broadbands, definition and operation of bandwidth parts (BWPs), novel channel coding methods such as a low density parity-check (LDPC) code for large amount of data transmission and a polar code for highly reliable transmission of control information, Layer 2 (L2) pre-processing, and network slicing for providing a dedicated network tailored to a specific service.

Currently, there are ongoing discussions regarding improvement and performance enhancement of initial 5G mobile communication technologies in view of services to be supported by 5G mobile communication technologies, and there has been physical layer standardization regarding technologies such as vehicle-to-everything (V2X) for aiding driving determination by autonomous vehicles based on information regarding positions and states of vehicles transmitted by the vehicles and for enhancing user convenience, new radio (NR)-Unlicensed (U) aimed at system operations conforming to various regulation-related requirements in unlicensed bands, NR UE (User Equipment) power saving, non-terrestrial network (NTN), which is UE-satellite direct communication for providing coverage in an area in which communication with terrestrial networks is unavailable, and positioning.

There has also been ongoing standardization in air interface architecture/protocol regarding technologies such as industrial Internet of things (IIoT) for supporting new services through interworking and convergence with other industries, integrated access and backhaul (IAB) for providing a node for network service area expansion by supporting a wireless backhaul link and an access link in an integrated manner, mobility enhancement including conditional handover and dual active protocol stack (DAPS) handover, and two-step random access for simplifying random access procedures (2-step RACH for NR).

There also has been ongoing standardization in system architecture/service regarding a 5G baseline architecture (e.g., service based architecture or service based interface) for combining network functions virtualization (NFV) and software-defined networking (SDN) technologies, and mobile edge computing (MEC) for receiving services based on UE positions.

As 5G mobile communication systems are commercialized, an exponentially increasing number of connected devices will be connected to communication networks, and it is expected that enhanced functions and performances of 5G mobile communication systems and integrated operations of connected devices will be necessary. To this end, new research is scheduled in connection with extended reality (XR) for efficiently supporting augmented reality (AR), virtual reality (VR), mixed reality (MR), etc., 5G performance improvement and complexity reduction by utilizing artificial intelligence (AI) and machine learning (ML), AI service support, metaverse service support, and drone communication.

Such development of 5G mobile communication systems will serve as a basis for developing new waveforms for providing coverage in terahertz bands of 6G mobile communication technologies, multi-antenna transmission technologies such as full dimensional MIMO (FD-MIMO), array antennas and large-scale antennas, metamaterial-based lenses and antennas for improving coverage of terahertz band signals, high-dimensional space multiplexing technology using orbital angular momentum (OAM), and reconfigurable intelligent surface (RIS), and also full-duplex technologies for increasing frequency efficiency of 6G mobile communication technologies and improving system networks, AI-based communication technologies for implementing system optimization by utilizing satellites and AI from the design stage and internalizing end-to-end AI support functions, and next-generation distributed computing technologies for implementing services at levels of complexity exceeding the limit of UE operation capability by utilizing ultra-high-performance communication and computing resources.

Definitions for other certain words and phrases are provided throughout this patent document. Those of ordinary skill in the art should understand that in many if not most instances, such definitions apply to prior as well as future uses of such defined words and phrases.

### SUMMARY

The present disclosure discloses a method and an apparatus for error correction coding in a communication system, more specifically, to error correction coding integrated with transmission diversity.

In one embodiment, an encoder apparatus in a communication system is provided. The encoder apparatus includes a polar encoder. The polar encoder is configured to identify a data word, obtain a transform input word comprising a data part derived from the data word and a fixed part, wherein a length of the data part is less than or equal to a sum of a length of the data word and a constant, and obtain a plurality of transform variables from the transform input word based on a polar transform. The encoder apparatus further includes a diversity mapper. The diversity mapper is configured to generate a diversity code array based on a diversity code array formation relation and a plurality of zero-error constraints, wherein, based on the diversity code array formation relation, an element of the diversity code array is associated with one of the plurality of transform variables, wherein at least one of the plurality of zero-error constraints is associated with a non-empty proper subset of rows of the diversity code array and the data part is uniquely identifiable from the subset of rows. The diversity mapper is further configured to transmit the diversity code array.

In another embodiment, a decoder apparatus in a communication system is provided. The decoder apparatus includes a diversity demapper. The diversity demapper is configured to identify a received diversity code array, wherein the received diversity code array corresponds to a transmitted diversity code array, the diversity code array is based on a diversity code array formation relation and a plurality of zero-error constraints, and each element of the diversity code array is associated, based on the diversity code array formation relation, with one of a plurality of transform variables, wherein the plurality of transform variables are related to the transform input word by a polar transform, the transform input word comprises a data part derived from a data word and a fixed part, a length of the data part is less than or equal to a sum of a length of the data word and a constant, at least one of the plurality of zero-error constraints is associated with a non-empty proper subset of rows of the diversity code array, and the data part is uniquely identifiable from the subset of rows. The diversity demapper is further configured to obtain, from the received diversity code array, a polar decoder input including an indicator indicating at least one element of the plurality of transform variables. The decoder apparatus further includes a polar decoder. The polar decoder is configured to decode the polar decoder input based on the polar transform to obtain a decoded data word.

In another embodiment, an encoding method in a communication system is provided. The encoding method includes a polar encoding step. The polar encoding step includes identifying a data word, obtaining a transform input word comprising a data part derived from the data word and a fixed part, wherein a length of the data part is less than or equal to a sum of a length of the data word and a constant, and obtaining a plurality of transform variables from the transform input word based on a polar transform. The encoding method further includes a diversity mapping step. The diversity mapping step includes generating a diversity code array based on a diversity code array formation relation and a plurality of zero-error constraints, wherein, based on the diversity code array formation relation, an element of the diversity code array is associated with one of the plurality of transform variables, wherein at least one of the plurality of zero-error constraints is associated with a non-empty proper subset of rows of the diversity code array and the data part is uniquely identifiable from the subset of rows. The diversity mapping step further includes transmitting the diversity code array.

In yet another embodiment, a decoding method in a communication system is provided. The decoding method includes a diversity demapping step. The diversity demapping step includes identifying a received diversity code array, wherein the received diversity code array corresponds to a transmitted diversity code array, the diversity code array is based on a diversity code array formation relation and a plurality of zero-error constraints, and each element of the diversity code array is associated, based on the diversity code array formation relation, with one of a plurality of transform variables, wherein the plurality of transform variables are related to the transform input word by a polar transform, the transform input word comprises a data part derived from a data word and a fixed part, a length of the data part is less than or equal to a sum of a length of the data word and a constant, at least one of the plurality of zero-error constraints is associated with a non-empty proper subset of rows of the diversity code array, and the data part is uniquely identifiable from the subset of rows. The diversity demapping step further includes obtaining, from the received diversity code array, a polar decoder input including an indicator indicating at least one element of the plurality of transform variables. The decoding method further includes a polar decoding step. The polar decoding step includes decoding the polar decoder input based on the polar transform to obtain a decoded data word.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a comprehensive understanding of the present disclosure and its advantages, reference is made to the following description, which should be read in conjunction with the accompanying drawings, wherein like reference numerals represent like parts:

FIG. 1 is a schematic diagram of a wireless network 100 in which embodiments of the present principles may be implemented according to certain aspects of the present disclosure;

FIG. 2A illustrates an example user equipment network in which embodiments of the present principles may be implemented according to certain aspects of the present disclosure;

FIG. 2B illustrates an example of an enhanced NodeB (eNB) network in which embodiments of present principles may be implemented according to certain aspects of the present disclosure;

FIG. 3 is a block diagram illustrating a communication system in which embodiments of a diversity code can be implemented in accordance with certain aspects of the present principles;

FIG. 4 is a flowchart that illustrates an encoding method in accordance with certain aspects of the present disclosure;

FIG. 5A is a diagram 500 illustrating the essential elements of a preferred embodiment of the encoder 320 in accordance with certain aspects of the present principles;

FIG. 5B illustrates an example of a preferred embodiment of the encoder, in accordance with certain aspects of the present principles;

FIG. 5C is a flowchart of a method for checking if a diversity code satisfies a plurality of zero-error constraints in accordance with certain aspects of the present principles;

FIG. 5D illustrates a first example of the zero-error check method depicted in FIG. 5C;

FIG. 5E illustrates a second example of the zero-error check method depicted in FIG. 5C;

FIG. 5F illustrates a third example of the zero-error check method depicted in FIG. 5C;

FIG. 5G illustrates a fourth example of the zero-error check method depicted in FIG. 5C;

FIG. 6A is a flowchart illustrating the steps of the ML-x method for constructing zero-error diversity codes in accordance with certain aspects of the present principles;

FIGS. 6B and 6C illustrate an example of the ML-x method depicted in FIG. 6A;

FIGS. 7A, 7B, and 7C are flowcharts and associated formulas illustrating the steps of the SC-x method for constructing zero-error diversity codes in accordance with certain aspects of the present principles;

FIGS. 7D and 7E illustrate an example of the SC-x method depicted in FIGS. 7A, 7B, and 7C;

FIGS. 8A and 8B are flowcharts illustrating the steps of the SC-u method for constructing zero-error diversity codes in accordance with certain aspects of the present principles;

FIG. 8C illustrates an example of the SC-u method depicted in FIGS. 8A and 8B;

FIG. 9 is a flowchart illustrating a decoding method in accordance with certain aspects the present disclosure;

FIG. 10 presents a simulation-based comparison of the frame error rate (FER) performance of example diversity code arrays constructed in accordance with certain aspects of the present principles;

FIG. 11 is a table that presents five implementation options for the encoder in accordance with certain aspects of the present principles.

### DETAILED DESCRIPTION

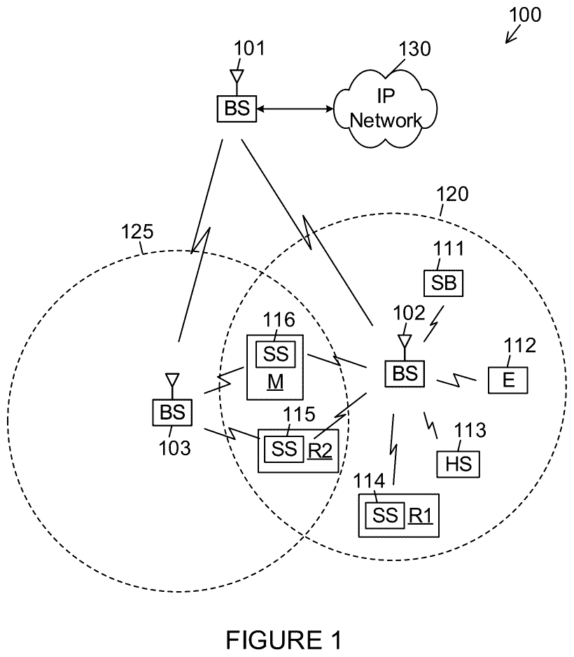

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

In emerging applications such as ultra-reliable low-latency communications (URLLC) there is a requirement to send short messages with ultra-high reliability and minimal latency over wireless channels affected by fading, interference, and thermal noise. Traditional methods to enhance the reliability of a given forward error-correcting coding (FEC) scheme through retransmissions, such as Hybrid-Automatic Repeat Request (HARQ), may not be compatible with the low latency requirement of certain URLLC usage scenarios. There is need for FEC methods that are integrated with transmission diversity so as to provide extreme reliability without retransmissions when such need arises. The present principles provide such a solution.

The present principles can be applied, provided that the channel in the system is capable of supporting transmission diversity, such as a channel consisting of multiple independently fading subchannels. For example, in an OFDM system, such subchannels may be obtained by using a multiple resource blocks that are sufficiently separated in frequency or time. Given such a channel and a FEC scheme with a specific encoder and decoder, the present principles introduce a diversity mapper between the encoder and the channel input, and a diversity demapper between the channel output and the FEC decoder, without requiring modifications to the encoder or the decoder. Effectively, the present principles upgrade the given channel to a higher-quality channel by integrating the channel with a diversity scheme that is tailored to the characteristics or the FEC scheme.

Polar coding is particularly well suited for use within or in combination with the present principles. In one aspect, the present principles can be viewed as an extension of polar coding, where a polar transform is augmented by a diversity mapper. Polar coding for fading channels has been extensively studied. For example, various techniques, including interleaving, signal shaping, modulation, and diversity transmission, have been integrated with polar coding to enhance resilience against fading and outages. Alternative diversity coding schemes in prior art based on Reed-Solomon (RS) codes achieve high efficiency as RS codes are maximum distance separable (MDS), achieving the Singleton bound with equality. However, employing RS codes for diversity coding increases complexity, particularly at the receiver side in extracting soft information from received RS symbols. The present principles eliminate RS coding and offer seamless integration of a legacy FEC scheme with a custom-designed diversity coding scheme, while using a common alphabet for both schemes. In preferred embodiments, the legacy FEC scheme is a binary polar code and the diversity coding scheme utilizes the binary variables generated in the course of computing a binary polar transform. The present principles minimize the complexity of soft information extraction at the receiver and integrate seamlessly with legacy polar decoders.

The present principles are based on a novel reliability criterion referred to as “zero-error diversity coding.” Zero-error diversity codes can be used as a supplementary method for enhancing the reliability of an existing polar coding scheme in a transparent manner, without requiring modifications to the existing polar coding scheme. This transparency is crucial when the existing scheme is already standardized or implemented in ASIC, where modifications may be impractical or costly. This transparency also enables “future-proofing” of an existing polar code implementation, which is essential in modern wireless communication standards as future use cases and their FEC requirements often cannot be anticipated at the time of standardization.

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged communication system.

Aspects, features, and advantages of the disclosure are readily apparent from the following detailed description, simply by illustrating a number of particular embodiments and implementations, including the best mode contemplated for carrying out the disclosure. The disclosure is also capable of other and different embodiments, and its several details can be modified in various obvious respects, all without departing from the spirit and scope of the disclosure. Accordingly, the drawings and description are to be regarded as illustrative in nature, and not as restrictive. The disclosure is illustrated by way of example, and not by way of limitation, in the figures of the accompanying drawings.

In the following, for brevity, both FDD and TDD are considered as the duplex method for both DL and UL signaling.

Although exemplary descriptions and embodiments to follow assume orthogonal frequency division multiplexing (OFDM) or orthogonal frequency division multiple access (OFDMA), this disclosure can be extended to other OFDM-based transmission waveforms or multiple access schemes such as filtered OFDM (F-OFDM).

The present disclosure covers several components which can be used in conjunction or in combination with one another, or can operate as standalone schemes.

FIG. 1 is a schematic diagram of a wireless network 100 in which embodiments of the present principles may be implemented according to certain aspects of the present disclosure. The wireless network 100 is for illustration only and does not limit the scope of the present disclosure. In particular, the present disclosure can be applied in wireline communication systems as well as wireless systems.

The wireless network 100 includes an eNodeB (eNB) 101, an eNB 102, and an eNB 103. The eNB 101 communicates with the eNB 102 and the eNB 103. The eNB 101 also communicates with at least one Internet Protocol (IP) network 130, such as the Internet, a proprietary IP network, or other data network.

Depending on the network type, other well-known terms may be used instead of “eNodeB” or “eNB,” such as “base station,” “BS,” “gNodeB,” or “access point.” For the sake of convenience, the terms “eNodeB” and “eNB” are used in this patent document to refer to network infrastructure components that provide wireless access to remote terminals. Also, depending on the network type, other well-known terms may be used instead of “user equipment” or “UE,” such as “mobile station” (or “MS”), “subscriber station” (or “SS”), “remote terminal,” “wireless terminal,” or “user device.” For the sake of convenience, the terms “user equipment” and “UE” are used in this patent document to refer to remote wireless equipment that wirelessly accesses an eNB, whether the UE is a mobile device (such as a mobile telephone or smartphone) or is normally considered a stationary device (such as a desktop computer or vending machine).

The eNB 102 provides wireless broadband access to the IP network 130 for a first plurality of user equipments (UEs) within a coverage area 120 of the eNB 102. The first plurality of UEs includes a UE 111, which may be located in a small business (SB); a UE 112, which may be located in an enterprise (E); a UE 113, which may be located in a WiFi hotspot (HS); a UE 114, which may be located in a first residence (R1); a UE 115, which may be located in a second residence (R2); and a UE 116, which may be a mobile device (M) like a cell phone, a wireless laptop, a wireless personal digital assistant (PDA), tablet, or the like. The eNB 103 provides wireless broadband access to the IP network 130 for a second plurality of UEs within a coverage area 125 of the eNB 103. The second plurality of UEs includes the UE 115 and the UE 116. In some embodiments, one or more of the eNBs 101-103 may communicate with each other and with the UEs 111-116 using WiFi, WiMAX, 3G, 4G, long-term evolution (LTE), LTE-A, 5G, or other present or future advanced wireless communication techniques.

Dotted lines show the approximate extents of the coverage areas 120 and 125, which are shown as approximately circular for the purposes of illustration and explanation only. It should be clearly understood that the coverage areas associated with eNBs, such as the coverage areas 120 and 125, may have other shapes, including irregular shapes, depending upon the configuration of the eNBs and variations in the radio environment associated with natural and man-made obstructions.

As described in more detail below, one or more of eNB 101, eNB 102 and eNB 103 include 2D antenna arrays that can be used in conjunction with embodiments of the present disclosure. In some embodiments, one or more of eNB 101, eNB 102 and eNB 103 support the codebook design and structure for systems having 2D antenna arrays.

Although FIG. 1 illustrates one example of the wireless network 100, various changes may be made to FIG. 1. For example, the wireless network 100 could include any number of eNBs and any number of UEs in any suitable arrangement. Also, the eNB 101 could communicate directly with any number of UEs and provide those UEs with wireless broadband access to the IP network 130. Similarly, each eNB 102-103 could communicate directly with the IP network 130 and provide UEs with direct wireless broadband access to the IP network 130. Further, the eNB 101, 102, and/or 103 could provide access to other or additional external networks, such as external telephone networks or other types of data networks.

The embodiments of the present principles depicted in the figures and described below may be implemented in an eNB (such as eNB 102) and/or a UE (such as UE 116), as described in further detail below.

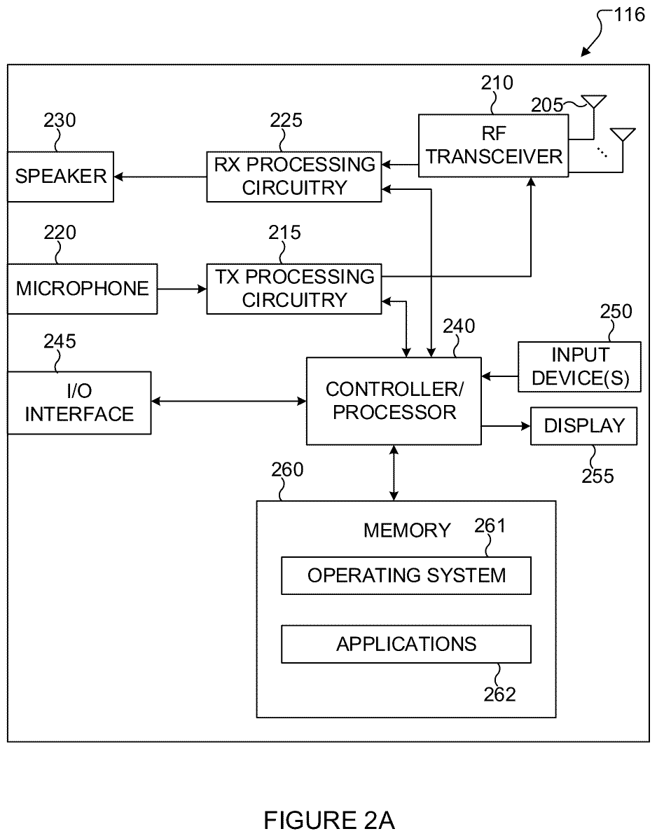

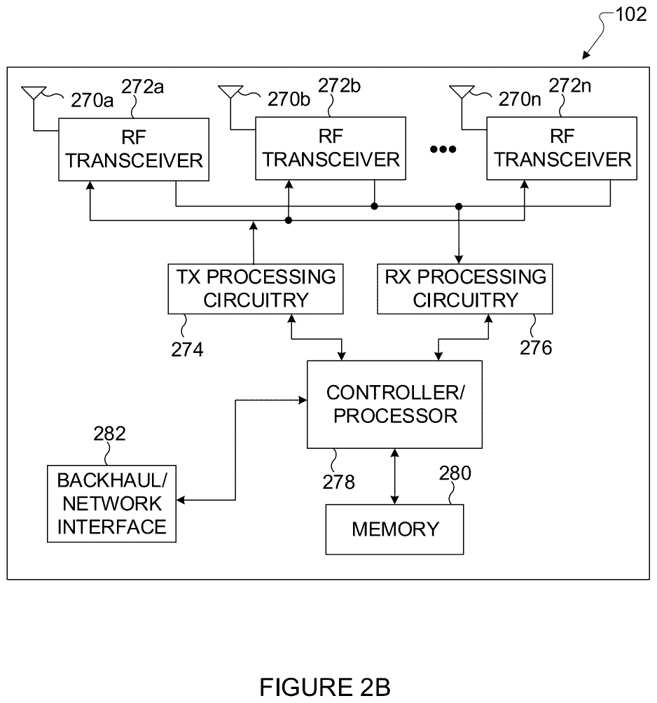

FIG. 2A illustrates an example user equipment network in which embodiments of the present principles may be implemented according to certain aspects of the present disclosure. The embodiment of the UE 116 illustrated in FIG. 2A is for illustration only, and the UEs 111-116 of FIG. 1 could have the same or similar configuration. However, UEs come in a wide variety of configurations, and FIG. 2A does not limit the scope of the present disclosure to any particular implementation of a UE.

The UE 116 includes an antenna 205, a radio frequency (RF) transceiver 210, a transmit (TX) processing circuitry 215, a microphone 220, and a receive (RX) processing circuitry 225. The UE 116 also includes a speaker 230, a controller/processor 240, an input/output (I/O) interface 245, input device(s) 250 (such as a keypad), a display 255, and a memory 260. The memory 260 includes a basic operating system (OS) program 261 and one or more applications 262. Either the basic OS program 261, one of the applications 262, or some combination thereof may implement programming for employing the present principles as described in the various embodiments herein.

The RF transceiver 210 receives, from the antenna 205, an incoming RF signal transmitted by an eNB of the wireless network 100. The RF transceiver 210 may down-convert the incoming RF signal to generate an intermediate frequency (IF) or baseband signal which would be sent to the RX processing circuitry 225. The RX processing circuitry 225 transmits the processed signal to the speaker 230 (such as for voice data) or to the controller/processor 240 for further processing (such as for web browsing data).

The TX processing circuitry 215 receives, as at least some input data for the source data block, analog or digital voice data from the microphone 220 or other outgoing baseband data (such as web data, e-mail, or interactive video game data) from the controller/processor 240. The RF transceiver 210 receives the outgoing processed baseband or IF signal from the TX processing circuitry 215 and up-converts the baseband or IF signal to an RF signal that is transmitted via the antenna 205.

The controller/processor 240 can include one or more processors or other processing devices and execute the basic OS program 261 stored in the memory 260 in order to control the overall operation of the UE 116. For example, the controller/processor 240 could control the reception of forward channel signals and the transmission of reverse channel signals by the RF transceiver 210, the RX processing circuitry 225, and the TX processing circuitry 215 in accordance with well-known principles. In some embodiments, the controller/processor 240 includes at least one programmable microprocessor or microcontroller, while in other embodiments the main processor includes dedicated circuitry as well as (optionally) programmable logic or processing circuits. The controller/processor 240 may comprise or correspond to an application processor (AP) and/or a communication processor (CP). In one example, the AP and/or CP may be implemented in separate integrated circuit (IC) packages. In another example, the AP and/or CP may be integrated into a single IC package or implemented as a system on chip (SoC).

The controller/processor 240 is also capable of executing other processes and programs resident in the memory 260, such as operations for channel quality measurement and reporting for systems having 2D antenna arrays. The controller/processor 240 can move data and/or instructions into or out of the memory 260 as required by an executing process. In some embodiments, the controller/processor 240 is configured to execute the applications 262 based on the basic OS program 261 or in response to signals received from eNBs or an operator. The controller/processor 240 is also coupled to the I/O interface 245, which provides the UE 116 with the ability to connect to other devices such as laptop computers and handheld computers. The I/O interface 245 is the communication path between these accessories and the controller/processor 240. The controller/processor 240 can be configured to perform the functions performed by the encoder, diversity mapper, decoder, and diversity demapper described in the following description.

The controller/processor 240 is also coupled to the input device(s) 250 (which may simply be a single button or may be an array or other set of buttons) and the display 255. The operator of the UE 116 can use the input device(s) 250 to enter data into the UE 116. The display 255 may be a touch screen display or other display capable of rendering text and/or at least limited graphics, such as from web sites, and receiving touch inputs by a user in accordance with known practices.

The memory 260 is coupled to the controller/processor 240, and at least a part of the memory 260 could include a random access memory (RAM), and another part of the memory 260 could include a Flash memory or other read-only memory (ROM). The memory 260 may be implemented as one or more separate memory devices, or may be integrated into the same chip or package as the controller/processor 240, thereby forming a SoC or a multi-chip package. While the controller/processor 240 and memory 260 are shown as separate blocks in FIG. 2A, they may be physically combined or implemented in a single chip, and memory 260 may include embedded logic or processing elements that support controller/processor 240 functionality.

Although FIG. 2A illustrates one example of the UE 116, various changes may be made to FIG. 2A. For example, various components in FIG. 2A could be combined, further subdivided, or omitted and additional components could be added according to particular needs. As a particular example, the controller/processor 240 could be divided into multiple processors, such as one or more central processing units (CPUs), one or more application specific integrated circuits (ASICs), one or more field programmable gate arrays (FPGAs), and one or more graphics processing units (GPUs). Also, while FIG. 2A illustrates the UE 116 configured as a mobile telephone or smartphone, UEs could be configured to operate as other types of mobile or stationary devices.

FIG. 2B illustrates an example of an enhanced NodeB (eNB) network in which embodiments of present principles may be implemented according to certain aspects of the present disclosure. The embodiment of the eNB 102 shown in FIG. 2B is for illustration only, and other eNBs of FIG. 1 could have the same or similar configuration. However, eNBs come in a wide variety of configurations, and FIG. 2B does not limit the scope of the present disclosure to any particular implementation of an eNB. It is noted that the eNB 101 and the eNB 103 can include the same or similar structure as the eNB 102.

As shown in FIG. 2B, the eNB 102 includes multiple antennas 270a-270n, multiple RF transceivers 272a-272n, a transmit (TX) processing circuitry 274, and a receive (RX) processing circuitry 276. In certain embodiments, one or more of the multiple antennas 270a-270n include 2D antenna arrays. The eNB 102 also includes a controller/processor 278, a memory 280, and a backhaul or network interface 282.

The RF transceivers 272a-272n receive, from the antennas 270a-270n, incoming RF signals, such as signals transmitted by UEs or other eNBs. The RF transceivers 272a-272n down-convert the incoming RF signals to generate IF or baseband signals. The IF or baseband signals are sent to the RX processing circuitry 276, which generates processed signals by filtering, decoding, and/or digitizing the baseband or IF signals. The RX processing circuitry 276 transmits the processed signals to the controller/processor 278 for further processing.

The TX processing circuitry 274 receives at least some input data. The TX processing circuitry 274 implements circuits to encode, multiplex, and/or digitize the outgoing baseband data to generate processed signals. The RF transceivers 272a-272n receive the outgoing processed signals from the TX processing circuitry 274 and up-converts the baseband or IF signals to RF signals that are transmitted via the antennas 270a-270n.

The controller/processor 278 can include one or more processors or other processing devices that control the overall operation of the eNB 102. For example, the controller/processor 278 could control the reception of forward channel signals and the transmission of reverse channel signals by the RF transceivers 272a-272n, the RX processing circuitry 276, and the TX processing circuitry 274 in accordance with well-known principles. The controller/processor 278 could support additional functions as well, such as more advanced wireless communication functions. Any of a wide variety of other functions could be supported in the eNB 102 by the controller/processor 278. In some embodiments, the controller/processor 278 includes at least one microprocessor or microcontroller, while in other embodiments the main processor includes dedicated circuitry (e.g., for controlling encoding and decoding processes, code puncturing and/or shortening processes, data mapping, etc.) as well as (optionally) programmable logic or processing circuits. The controller/processor 278 can be configured to perform the functions performed by the encoder, diversity mapper, decoder, and diversity demapper described in the following specification.

The controller/processor 278 is also capable of executing programs and other processes resident in the memory 280, such as a basic OS. The controller/processor 278 is also capable of supporting channel quality measurement and reporting for systems having 2D antenna arrays. In some embodiments, the controller/processor 278 supports communications between entities. The controller/processor 278 can move data and/or instructions into or out of the memory 280 as required by an executing process.

The controller/processor 278 is also coupled to the backhaul or network interface 282. The backhaul or network interface 282 allows the eNB 102 to communicate with other devices or systems over a backhaul connection or over a network. The network interface 282 could support communications over any suitable wired or wireless connection(s). For example, when the eNB 102 is implemented as part of a cellular communication system (such as one supporting 3G, 4G, 5G, LTE, or LTE-A), the interface 282 could allow the eNB 102 to communicate with other eNBs over a wired or wireless backhaul connection. When the eNB 102 is implemented as an access point, the network interface 282 could allow the eNB 102 to communicate over a wired or wireless local area network or over a wired or wireless connection to a larger network (such as the Internet). The interface 282 includes any suitable structure supporting communications over a wired or wireless connection, such as an Ethernet or RF transceiver.

The memory 280 is coupled to the controller/processor 278. Part of the memory 280 could include a RAM, and another part of the memory 280 could include a Flash memory or other ROM. In certain embodiments, a plurality of instructions is stored in memory. The instructions are configured to cause the controller/processor 278 to perform the systematic and/or non-systematic encoding or decoding processes, shortening processes, data mapping, etc.

Although FIG. 2B illustrates one example of the eNB 102, various changes may be made to FIG. 2B. For example, the eNB 102 could include any number of each component shown. As a particular example, an access point could include a number of instances of the network interface 282, and the controller/processor 278 could support routing functions to route data between different network addresses. As another particular example, while shown as including a single instance of the TX processing circuitry 274 and a single instance of the RX processing circuitry 276, the eNB 102 could include multiple instances of each (such as one per RF transceiver).

For any set A, the notation a E A indicates that a is an element of A, A^{c} denotes the complement A in a specified universal set, and |A| denotes the size (cardinality) of A. The notation Ø denotes the empty set. A set A is called non-empty if |A|>0. For any two sets A and B, the notation A⊂B means that A is a subset of B, which includes the possibility that A=B. A set A is called a proper subset of a set B if A⊗B and |A|<|B|. A set A is called a non-empty proper subset of a set B if A⊂B and 0<|A|<|B|. The symbols ∨, ∧, ⊕, and ¬ denote the logical operators OR, AND, XOR, and NOT, respectively.

The terms “word” and “array” refer to collections of data that are arranged into one-dimensional and two-dimensional structures, respectively. The elements of words and arrays may correspond to various types of numbers, parameters, or signals in a system.

A word is a one-dimensional collection such as v=(v₁, v₃, . . . vₙ) indexed by a single set of integers Iᵥ={1, 2, . . . , n}, where n is referred to as the length of v, and Iᵥ as the index set of v. The term vᵢ is referred to as an ith element of v, or an ith coordinate of v, or an element in the ith position of v. For any subset A⊂{1, 2, . . . , n}, the notation v_{A} denotes the subword v_{A}=(vᵢ: i∈A) consisting of elements of the word v with indices in A. The elements of v are listed in increasing index order in v_{A}. For example, for v=(v₁, v₂, . . . , v₈) and A={2, 5, 3, 8, 1}, we have v_{A}=(v₁, v₂, v₃, v₄, v₅, v₈). The elements of a word v may be numerical or non-numerical. For example, the elements of a word may represent binary data emitted by a source, in which case they may take the values 0 or 1. In another example, the elements of a word may represent symbols sent over a channel, in which case they may belong to a modulation alphabet. In a third example, the elements of a word may represent log-likelihood rations produced by a demapper between a channel and a decoder, in which case they may be real numbers.

An array is a collection of words such as

$$V = [ \begin{matrix}{v}_{1} \\ ⋮ \\ {v}_{m}\end{matrix} ] ,$$

wherein m denotes the number of words in V, and vᵢ denotes an ith word of V, 1≤i≤m. The ith row of V is a word of the form vᵢ=(v_{i,1}, v_{i,2}, . . . , v_{i,n}_{ᵢ}), wherein n; denotes the length of vᵢ. Different rows of V may have different lengths; i.e., the lengths n₁, n₂, . . . , nₘ need not be the same. The sum n₁+2+ . . . +nₘ is referred to as the length of the array V. The largest of the row lengths {n₁, n₂, . . . , nₘ} is referred to as the number of columns of V. An array is also denoted V=[v_{i,j}: 1≤i≤m, 1≤j≤nᵢ], where v_{i,j} is referred to as the (i, j)th element of V, or the element in the (i, j)th position of V. We sometimes use the notation (V)_{i,j} to denote v_{i,j}. The index set of an array V=[v_{i,j}: 1≤i≤m, 1≤j≤nᵢ] is defined as Iᵥ={(i, j): 1≤i≤m, 1≤j≤nᵢ}. The index set of an array is the set of all available positions in the array V. In general, an array is displayed with the aid of a special symbol “-” to denote any “null” elements in the array; for example,

$$V = [ \begin{matrix}{v}_{1 , 1} & {v}_{1 , 2} & {v}_{1 , 3} & {v}_{1 , 4} \\ {v}_{2 , 1} & {v}_{2 , 2} & {v}_{2 , 3} & - \\ {v}_{3 , 1} & {v}_{3 , 2} & - & - \\ {v}_{4 , 1} & {v}_{4 , 2} & {v}_{4 , 3} & -\end{matrix} ]$$

represents an irregular array V with row lengths n₁=4, n₂=3, n₃=2, n₄=3, and total length n₁+n₂+3+n₄=12.

An array V is called regular if all rows of V have the same length; otherwise, it is called irregular. We say that V is an m×n regular array if V is a regular array with m rows and n columns. For an m×n regular array V, and any two sets A⊂{1, 2, . . . , m} and B⊂{1, 2, . . . , n}, the notation V_{A,B} denotes the subarray V_{A,B}=[v_{i,j}: i∈A, j∈B], where the elements of V_{A,B} are listed in the same relative order as they appear in V. For example, for

$$[ \begin{matrix}{v}_{1 , 1} & {v}_{1 , 2} & {v}_{1 , 3} & {v}_{1 , 4} \\ {v}_{2 , 1} & {v}_{2 , 2} & {v}_{2 , 3} & {v}_{2 , 4} \\ {v}_{3 , 1} & {v}_{3 , 2} & {v}_{3 , 3} & {v}_{3 , 4} \\ {v}_{4 , 1} & {v}_{4 , 2} & {v}_{4 , 3} & {v}_{4 , 4}\end{matrix} ] , A = \{ 2 , 3 , 1 \} , and$$

$$B = \{ 1 , 4 , 2 \} , we have {V}_{A , B} = [ \begin{matrix}{v}_{1 , 1} & {v}_{1 , 2} & {v}_{1 , 4} \\ {v}_{2 , 1} & {v}_{2 , 2} & {v}_{2 , 4} \\ {v}_{3 , 1} & {v}_{3 , 2} & {v}_{3 , 4}\end{matrix} ] .$$

Given an array V=[V_{i,j}: 1≤i≥m, 1≤j≤n], the notation vec(V) denotes the word (v_{1,1}, . . . , v_{1,n}_{₁}, v_{2,1}, . . . , v_{2,n}_{₂}, . . . , v_{m,1}, . . . , v_{m,n}_{ₘ})). For example, if

$$V = [ \begin{matrix}{v}_{1 , 1} & {v}_{1 , 2} & {v}_{1 , 3} & {v}_{1 , 4} \\ {v}_{2 , 1} & {v}_{2 , 2} & {v}_{2 , 3} & - \\ {v}_{3 , 1} & {v}_{3 , 2} & - & - \\ {v}_{4 , 1} & {v}_{4 , 2} & {v}_{4 , 3} & -\end{matrix} ] ,$$

then vec(V)=(v_{1,1}, v_{1,2}, v_{1,3}, v_{1,4}, v_{2,1}, v_{2,2}, v_{2,3}, v_{3,1}, v_{3,2}, v_{4,1}, v_{4,2}, v_{4,3}). Sometimes a word v=(v₁, v₂, . . . vₙ) is given and the task is to construct an array V from v, where the number of rows in V is specified as a fixed parameter m but the number of columns of V is subject to choice. By default, the number of columns of V is chosen as k=[n/m], where [n/m] denotes the integer greater than or equal to n/m. The array V is populated with the elements of v by filling k elements into the top m−(m [n/m]−n) rows and (k−1) elements into the bottom (m [n/m]−n) rows. The filling starts at the top row, each row is filled from left to right with the specified number of elements before moving to the next row. For instance, if n=14 and m=4, the default method yields the array

$$V = [ \begin{matrix}{v}_{1} & {v}_{2} & {v}_{3} & {v}_{4} \\ {v}_{5} & {v}_{6} & {v}_{7} & {v}_{8} \\ {v}_{9} & {v}_{10} & {v}_{11} & - \\ {v}_{12} & {v}_{13} & {v}_{14} & -\end{matrix} ] .$$

We define balanced row-major order as a method of constructing an array V from a word v. In this method, V is populated with the elements of v as described above.

To describe various encoding operations, we use vectors and matrices over a vector space. Vectors represent points in a vector space and matrices represent linear operators on vectors. In this description, we regard vectors as special cases of words and matrices as special cases of regular arrays. So, the terminology and notation described above for words and regular arrays apply to words and matrices, respectively. For an element aᵢⱼ of a matrix A, we call i the row index and j the column index of a_{i,j}. We write A^{T} to denote the transpose of a matrix A; thus, A^{T} is the matrix with (A^{T})_{j,i}=(A)_{i,j}. If A is an invertible matrix, we denote the inverse of A by A⁻¹. Given two matrices A and B, the notation AB denotes the product of A and B. Given a vector v and a matrix A, we denote their product by vA. For these products to make sense, the matrices and vectors involved must have compatible dimensions. The Kronecker product of any two matrices A and B is defined as the (ms)×(nt) matrix

$$A ⊗ B = [ \begin{matrix}{a}_{1 , 1} B & … & {a}_{1 , n} B \\ ⋮ & ⋱ & ⋮ \\ {a}_{m , 1} B & … & {a}_{m , n} B\end{matrix} ] .$$

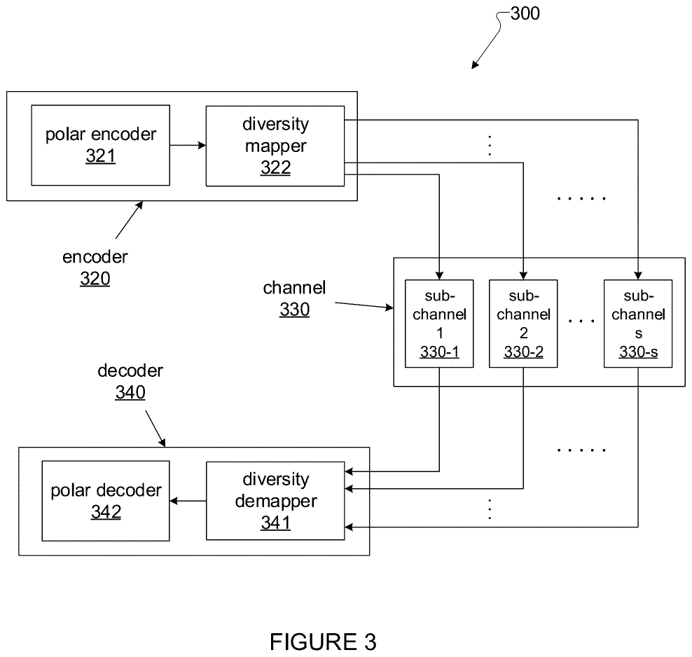

FIG. 3 is a block diagram illustrating a communication system 300 in which embodiments of a diversity code can be implemented in accordance with certain aspects of the present principles. FIG. 3 provides a high-level overview of the overall system, including both an encoder and a decoder for the diversity code, as well as their interaction through a communication channel. At this stage, no specific aspects of the present principles or implementation details are depicted, offering a general framework for understanding data flow within the system.

The communication system 300 comprises an encoder 320 connected, a channel 330 connected to the encoder 320, and a decoder 340 connected to the channel 330, wherein the encoder 320 is configured to identify a data word, encode the data word to a diversity code array from a diversity code, and transmit the diversity code array over the channel 330, wherein the decoder 340 is configured to identify a received diversity code array at an output of the channel 330, and decode the received diversity code array to obtain a decoded data word, wherein the encoder 320 comprises a polar encoder 321 and a diversity mapper 322, the decoder 340 comprises a diversity demapper 341 and a polar decoder 342, wherein the polar encoder 321 and the polar decoder 342 operate based on a polar transform.

The data word may include voice, video, sensor readings, or any other form of digital information. The encoder 320 implements an error-correcting code based on the present principles, generating a diversity code array based on the data word. The channel 330 may represent any physical or logical communication medium, such as a wired link (e.g., copper cable, fiber optic), a wireless connection (e.g., radio frequency, optical wireless), or a hybrid network architecture. During transmission, the data can be exposed to noise, interference, signal fading, or other impairments that introduce errors into the received signal. The channel 330 typically comprises signal processing functions such as modulation/demodulation, digital-to-analog (D/A) and analog-to-digital (A/D) conversion operations, amplification, filtering, equalization, and synchronization. At the receiver side, the decoder 340 processes the received signal in accordance with the present principles to mitigate the effects of channel-induced impairments and recover the transmitted data.

In typical embodiments, the channel 330 comprises a plurality of subchannels 330-1 through 330-s, where the number of subchannels s≥2 matches a number of rows in the diversity code array. Each row of the diversity code array is associated with a corresponding subchannel according to a subchannel assignment relation, and each row is transmitted via its respective subchannel. The subchannel assignment relation may be a one-to-one relation, associating each row with a unique subchannel. In some embodiments, the subchannel assignment relation may be a many-to-one relation, assign multiple rows to a single subchannel. In some embodiments, a number of subchannels may be larger than a number of rows, and a subset of subchannels may be selected based on available subchannel state information. The internal details of the channel 330 and the subchannels 330-1 through 330-s are beyond the scope of the present principles. The encoder 320 and decoder 340 interface with the channel over digital interfaces. For instance, if the diversity code array is over a binary alphabet, the encoder 320 typically sends a sequence of binary digits or symbols over each of the subchannels. These binary digits or symbols are modulated into real or complex-valued signals capable of being transmitted over the physical medium comprising the channel 330. The signals may be electrical, optical, or in another physical form. Different subchannels may utilize varying modulation formats, transmission time slots, or frequencies to enhance diversity.

The present principles focus on applications that require delivering data words from a transmitter to receiver with extreme reliability and low latency. To achieve this, diversity transmission techniques are employed across a plurality of subchannels 330-1 through 330-s. For example, the physical layer (PHY) resources for the subchannels may be assigned at different frequencies (carriers) to provide frequency domain diversity, at different time slots to provide time domain diversity, or across different antennas, antenna elements, or antenna polarization modes to provide spatial diversity. Typically, the number of subchannels s is a flexible configuration parameter that determines the order of transmission diversity. The encoder 320 and decoder 340 are designed to be adaptive with respect to the parameter s, allowing the system to accommodate various diversity orders as needed. The present principles are applicable for any s≥2; however, significant performance gains are demonstrated with s≤6.

The channel 330 is typically characterized at the decoder 340 by channel transition probabilities, which may depend on the channel state and are usually expressed as the conditional probability of observing a channel output given the channel input and the channel state. In some embodiments, the channel 330 and its subchannels may be modeled as conditionally independent given the channel state and the transmitted code array. Additionally, the subchannels may be modeled as conditionally memoryless given the channel state.

The channel output observed by the decoder 340 is typically a sequence of finite-precision real- or complex-valued signals that carry raw statistical information about the symbols transmitted at the channel input. Additionally, the channel output may include various forms of side information about the state of the plurality of subchannels 330-1 through 330-s, such as estimates of fading coefficients, outage events, received signal strengths, or signal-to-noise ratio (SNR) estimates. The present principles are designed to take full advantage of the availability of such channel state information (CSI) at the decoder 340, without requiring that CSI is available at the encoder 320. Based on the channel model and the CSI, the diversity demapper 341 processes the channel output, effectively inverting the processes at the diversity mapper 322, and generates a polar decoder input that can be readily used by the polar decoder 342 to generate a decoded data word.

Current and future wireless standards include control channels and signaling methods designed to coordinate an encoder and decoder, enabling them to leverage the present principles in rapidly changing wireless transmission environments. Typically, the encoder 320 and decoder 340 are configured by their respective control units, which are not shown in FIG. 3. In some embodiments of the present principles, the encoder 320 and decoder 340 operate as part of an adaptive coding and modulation system, controlled by a higher-layer protocol, such as a MAC layer resource allocation and scheduling algorithm. In such adaptive systems, the configurations of the encoder 320 and decoder 340 may vary with each use of the communication system 300, along with the channel 330 and the subchannels 330-1 through 330-s. For instance, the channel 330 may be reconfigured based on PHY layer resource assignments communicated to the encoder 320 and decoder 340 by a MAC layer entity.

A configuration consists of one or more configuration parameters. Some of these parameters for the encoder 320 and decoder 340 may be predefined or predetermined, while others may be signaled between the encoder and decoder, or determined by the encoder and/or decoder autonomously. In typical embodiments of the present principles, as described below, the configuration parameters for the encoder and decoder include the polar transform size, data word length, data part index set, polar code word length, channel interleaver, a plurality of zero-error constraints, number of rows in the diversity code array, length of each row in the diversity code array, among others. These configuration parameters are subject to various constraints.

For instance, the polar transform size may be restricted to powers of two, such as values between 8 and 1024. The data word length may be limited to positive integers smaller than the polar transform size. The plurality of zero-error constraints may be chosen from a predefined set of options. Additionally, there may be a number of predefined design types for the diversity code array, with a specific design type included in the encoder and decoder configuration. The encoder and decoder may be preconfigured with stored diversity code arrays, enabling selection through a unique identifier for a specific array.

The encoder and decoder may also be preconfigured to determine the data part index set and channel interleaver using predefined procedures, such as those defined by 5G NR standards, after determining the polar transform size and data word length. In some embodiments, configuration parameters may be set through signaling methods such as RRC signaling, MAC CE, or DCI. For example, up to k bits of signaling could specify a parameter with 2k or fewer preconfigured values.

The configuration of the polar encoder may further include details about the polar transform size and a method (e.g., identification) for forming the transform input word from the data word. In some embodiments of the present principles, the configuration may also specify rate-adaptation methods, such as shortening or puncturing. The transform input word may include redundant bits, such as cyclic redundancy checks (CRC) or dynamically frozen bits, derived from the data word using various techniques. In some cases, the data word itself may include redundant bits. When puncturing or shortening is applied, adjustments may be made to the transform input word or the transform output word accordingly.

Additionally, the configuration of the polar encoder may include information (e.g., identification) regarding permutation or interleaving operations to be applied to the transform input word, transform output word, or polar code word. In certain embodiments of the present principles, the polar encoder may specifically be a 5G NR polar encoder.

When the diversity mapper 322 and diversity demapper 341 are implemented as add-on features to an existing polar encoder and polar decoder, existing RRC signaling methods can be used to deliver the polar coding configuration parameters to the polar encoder and decoder. Additional signaling, such as RRC signaling, MAC CE, or DCI, is required to deliver the diversity code parameters to the diversity mapper and demapper. For backward compatibility with an existing polar coding system, RRC signaling should also include a message enabling a fallback mode that bypasses diversity coding while using polar coding.

In some embodiments of the present principles, the encoder 320 and decoder 340 in the communication system 300 are capable of operating under multiple configurations, providing flexibility in selecting a diversity code array to meet various operational constraints such as reliability, latency, and available communication resources. Such multi-configuration systems are common in current wireless standards like 5G and are expected to be a requirement in future 6G standards. When employing the present principles in systems with multiple configurations, a coordination problem arises between the encoder and decoder, specifically the need to ensure that both select compatible configurations. In some scenarios, the encoder configuration may be controlled by a medium access control (MAC) layer or entity, which transmits radio resource control (RRC) messages, while the decoder uses blind detection methods to determine the encoder's configuration. Alternatively, both the encoder and decoder may be configured by the MAC layer or entity via respective RRC messages. In some cases, the decoder may rely on blind detection to determine the encoder's configuration. Alternatively, a set of predefined configuration candidates (e.g., configuration-1, configuration-2, configuration-3) may be established through RRC messages, with one specific configuration (e.g., configuration-2) selected via a MAC control element (CE), downlink control information (DCI), or other Layer 1 (L1) signaling.

The present principles, as depicted in FIG. 3, utilize a modular architecture that separates error correction functions (polar encoder/decoder) from diversity transmission functions (diversity mapper/demapper). This design allows a polar encoder/decoder pair to be combined with different diversity mapper/demapper pairs, enhancing flexibility and enabling backward-compatible integration with legacy systems. For instance, a 5G NR-based polar encoder 321 can be paired with a diversity mapper 322 to address the reliability demands of 5G/6G ultra-reliable low-latency communication (URLLC) scenarios. This modular approach also supports future applications requiring extreme reliability while maintaining compatibility with existing standards.

The present principles provide extensive implementation flexibility due to the wide range of parameters that define the encoder 320 and decoder 340. These principles can be realized in hardware, software, or a combination of both. In some embodiments, the encoder 320 may be implemented at a base station and the decoder 340 at a user terminal, or vice versa. The principles support both real-time diversity code array design using algorithms and retrieval of pre-stored diversity code arrays from memory. It should be noted that various modifications can be made to the apparatus and methods described herein. For instance, operations presented in the figures or flowcharts may overlap, occur in parallel, follow a different order, or repeat multiple times. Additionally, certain operations may be omitted or substituted with alternative processes.

In some embodiments of the present principles, for a given configuration of the polar encoder 321 and polar decoder 342, the diversity mapper 322 and diversity demapper 341 may have a limited number of configuration options. In such cases, it may be preferable to preconfigure the diversity mapper and demapper with a set of pre-stored choices and use RRC signaling to indicate which option to employ. This approach eliminates the need for real-time diversity code array computation, reducing processing complexity and latency. Additionally, it allows the MAC layer (or MAC entity) to easily determine the PHY layer resource requirements for transmitting the diversity code array. In another embodiment, the MAC layer (or MAC entity) may compute a diversity code array in real-time and send its description to the encoder 320 and decoder 340. While this method introduces more overhead, it removes the restriction of limiting the parameter space to predefined selections.

After addressing system-level architectural considerations for deploying the present principles, we now focus on specific embodiments of the encoder 320 and decoder 340.

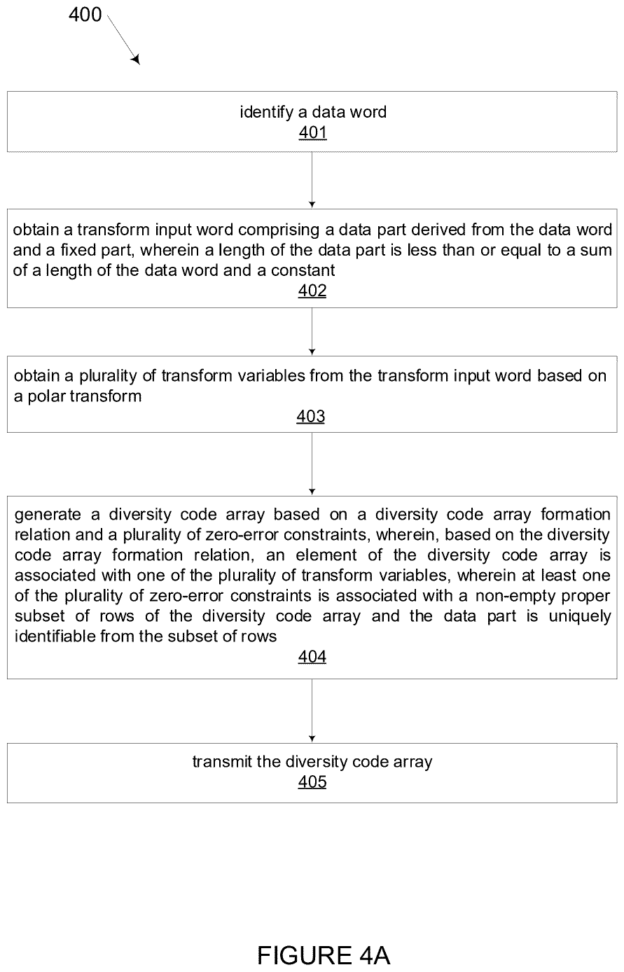

FIG. 4 is a flowchart that illustrates an encoding method 400 in accordance with certain aspects of the present disclosure. The encoding method 400 includes the steps of (401) identifying a data word, (402) obtaining a transform input word comprising a data part derived from the data word and a fixed part, wherein a length of the data part is less than or equal to a sum of a length of the data word and a constant, (403) obtaining a plurality of transform variables from the transform input word based on a polar transform, (404) generating a diversity code array based on a diversity code array formation relation and a plurality of zero-error constraints, wherein, based on the diversity code array formation relation, an element of the diversity code array is associated with one of the plurality of transform variables, wherein at least one of the plurality of zero-error constraints is associated with a non-empty proper subset of rows of the diversity code array and the data part is uniquely identifiable from the subset of rows, and (405) transmitting the diversity code array. Steps 401, 402, and 403 are executed by the polar encoder 321, while steps 404 and 405 are executed by the diversity mapper.

The following discussion elaborates on several technical terms referenced in the description of the encoder 320, including “polar transform,” “plurality of transform variables”, “diversity code array,” and “zero-error constraints.” Additionally, an explanation of the constraints imposed on various length parameters is provided.

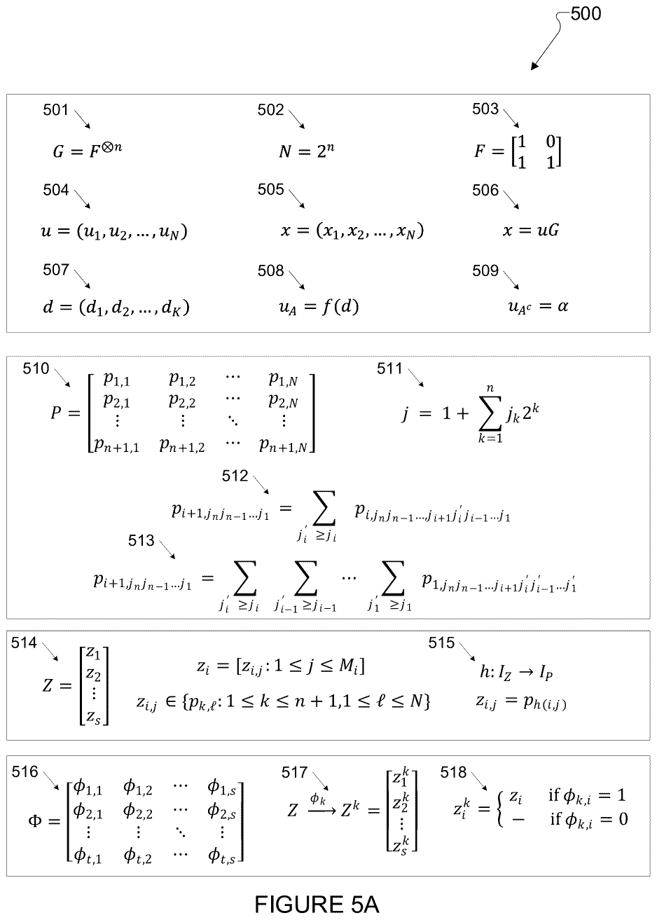

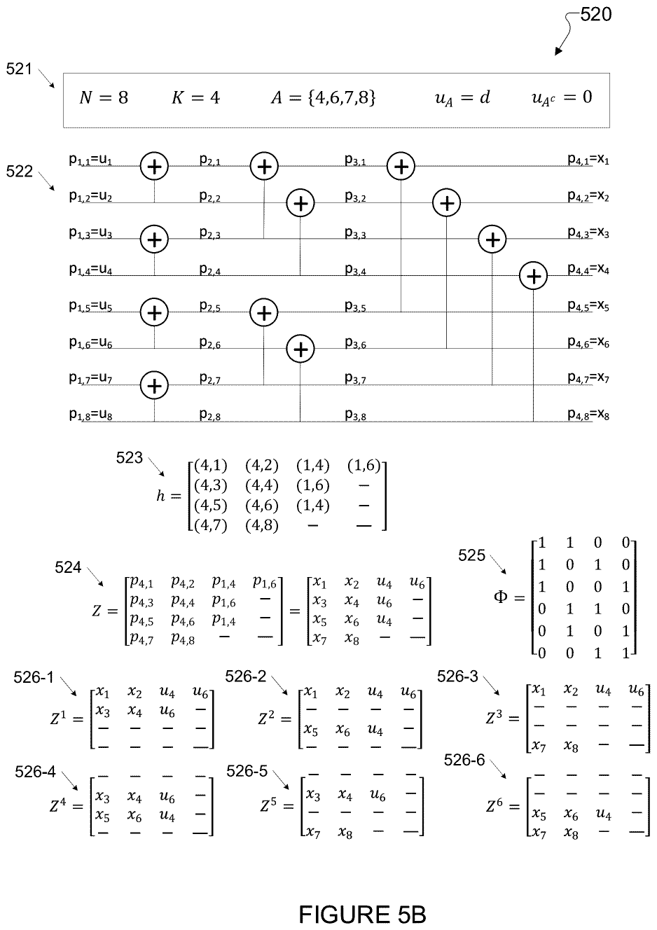

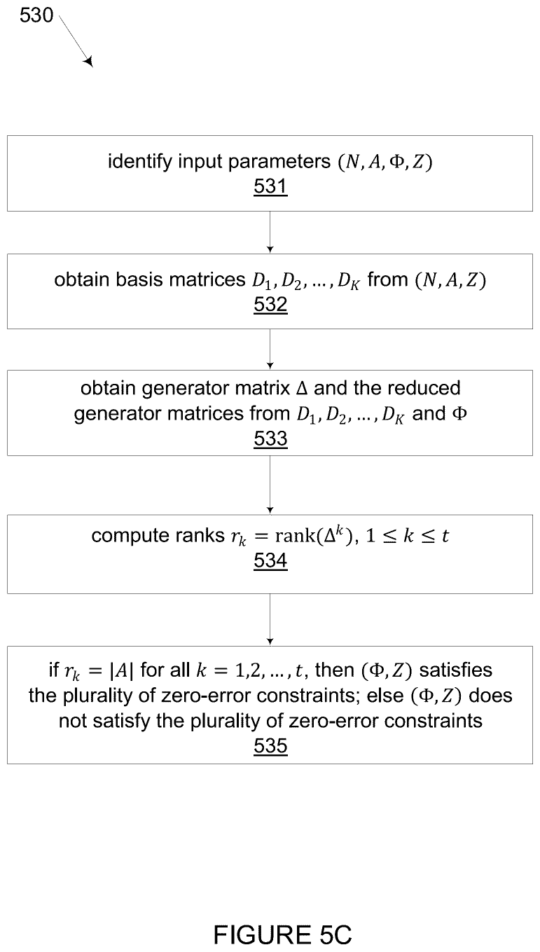

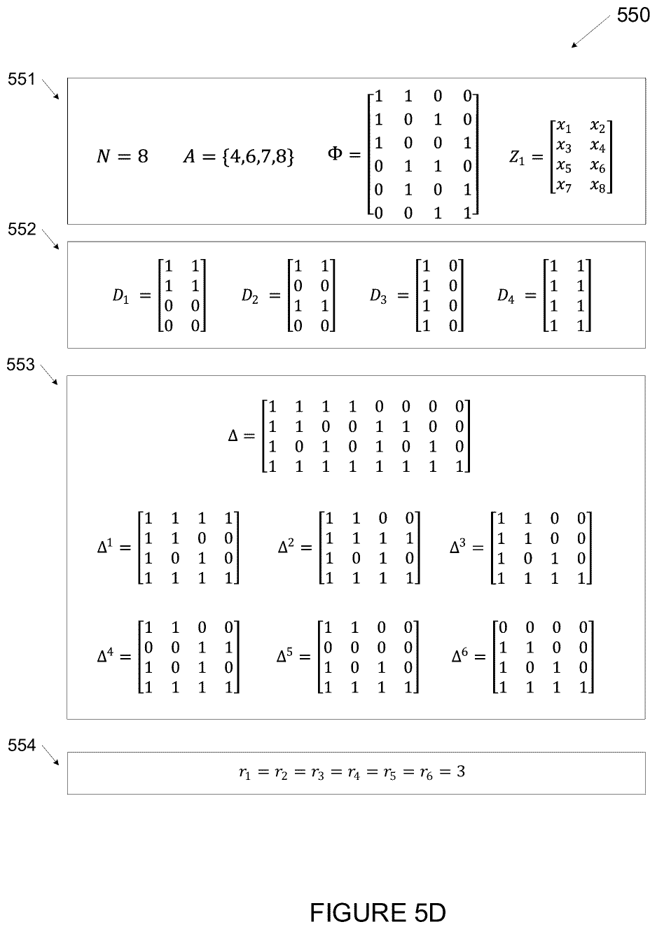

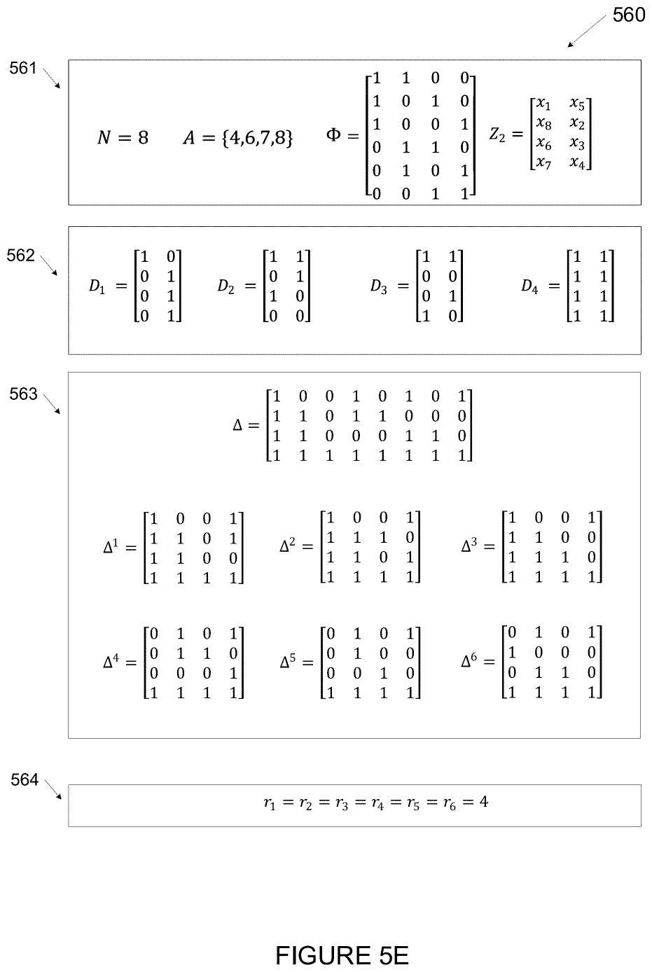

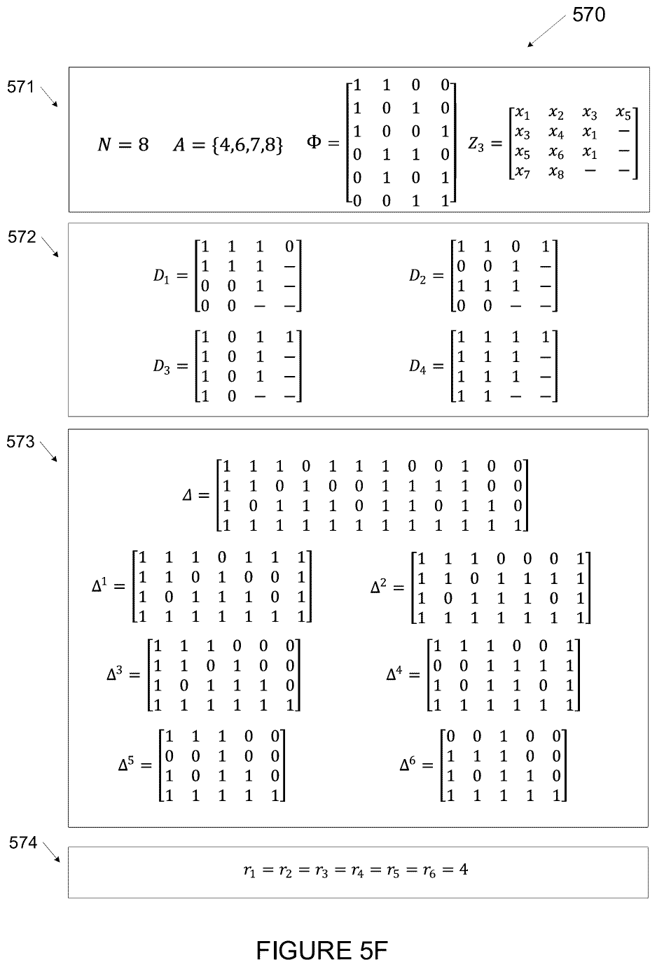

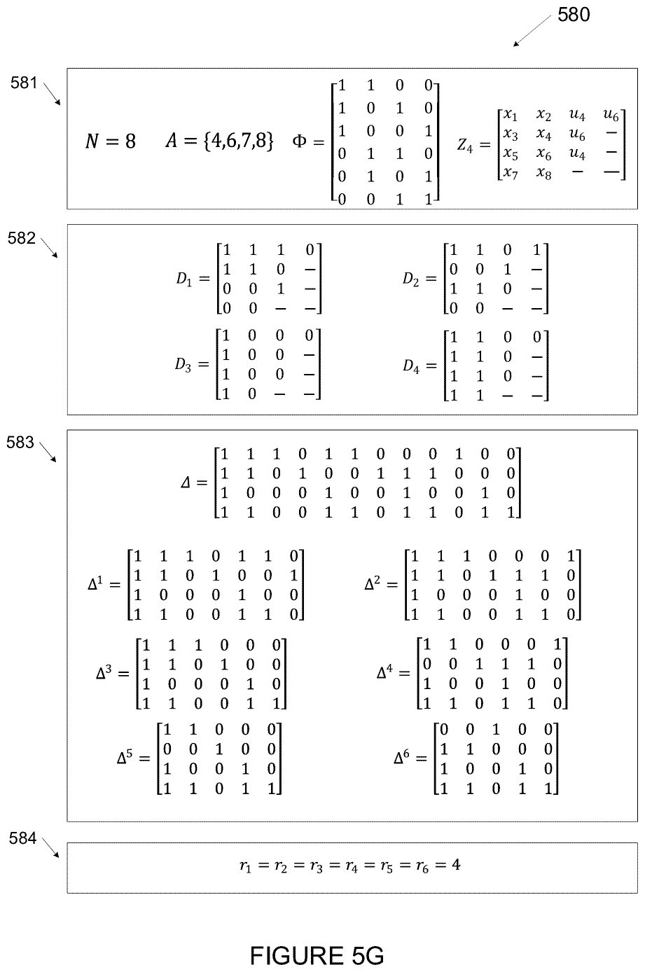

FIG. 5A is a diagram 500 illustrating the essential elements of a preferred embodiment of the encoder 320 in accordance with certain aspects of the present principles. The diagram 500 consists of four panels, each detailing a distinct component: (1) the polar encoder steps, (2) the fast polar transform operation, (3) the diversity mapper steps, and (4) the zero-error constraints in relation to a diversity code array. Each of these panels is discussed in detail below.

The present principles are compatible with any communication system 300 where the polar encoder 321 or the polar decoder 342 comprise a polar transform that can be represented by a matrix of the type G=F₁⊗F₂⊗ . . . Fₙ wherein F₁, F₂, . . . , Fₙ are a plurality of kernel matrices over a finite field GF(q), i.e., Fᵢ is a Nᵢ×Nᵢ lower triangular matrix with non-zero elements on the diagonal, and at least one non-zero element below the diagonal, with Nᵢ≥2, for all 1≤i>n. More generally, the polar encoder 321 or the polar decoder 342 may comprise various permutations, such as bit-reversals permutations, applied before or after the polar transform operation G. In the preferred embodiments and examples below, we consider the most basic forms of polar coding over the binary field GF(2) in order not to clutter the description with unnecessary detail. These specific embodiments and examples should not be interpreted as limiting the scope of the present principles.

To discuss a basic form of polar coding, we turn to the first panel in FIG. 5A, which illustrates a polar transform G=F^{⊗n} 501 over the binary field GF(2). The transform has size N=2ⁿ 502 and is defined by the nth Kronecker power F^{⊗n} of a kernel matrix F 503 for some n≥1. Given a vector u=(u₁, u₂, . . . , u_{N}) 504 over GF(2), we define the vector x=(x₁, x₂, . . . , x_{N}) 505 as the polar transform of u if the relation x=uG 506 holds, where the matrix multiplication is performed in the binary field GF(2). Based on the relation x=uG 506, the vectors u and x are referred to as the “transform input word” and “transform output word,” respectively.

In step 401 of the encoder method 400, the polar encoder 321 identifies a data word d=(d₁, d₂, . . . , d_{K}) 507, where K denotes a length of d. For the time being, we assume that 0≤K≤N; below, we will introduce further constraints on K that will narrow the scope of the present principles. In general, the data word d may have built-in redundancies (such as parity-checks inserted by higher layer protocols) or statistical correlations among the elements of d (as in speech or image data); however, in the preferred embodiments that we consider below, the encoder 320 and the decoder 340 treat the data word d as an arbitrary word that can take any value in the set of all possible binary K-tuples {0,1}^{K}.

In encoding step 402, a basic option is to obtain the transform input word u 504 from the data word d 507 by setting u_{A}=f(d) 508 and u_{A}_{^{c}}=α 509, wherein A is a subset of the transform input index set, A⊂Iᵤ={1, 2, . . . , N}, A^{c} denotes the complement of A in Iᵤ, f denotes a mapping from d to a word of length |A|, and α is a predefined word of length |A^{c}|=N−|A|. The parameters (A, f, α) jointly define a transform input word formation relation that relates the data word d to the transform input word u. We refer to A as a “data part index set,” and refer to u_{A} and u_{A}_{^{c}} as a “data part” and “fixed part” of the transform input word, respectively. In typical embodiments of the present principles, the communication system 300 is configured such that the polar decoder 342 is either fully provided with, or capable of reliably estimating, the parameters (A, f, α) prior to initiating decoding operations.

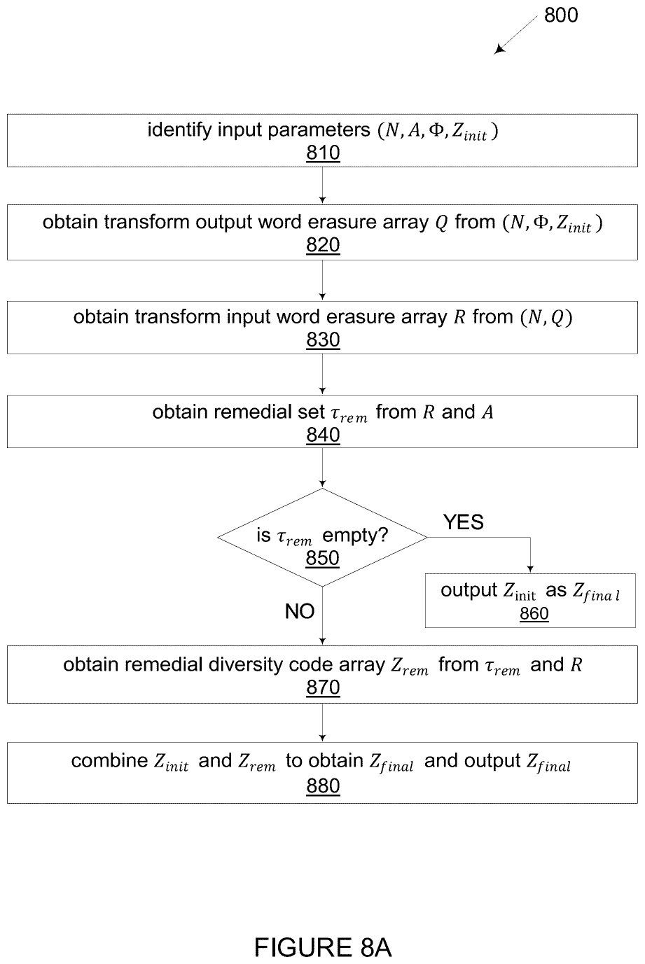

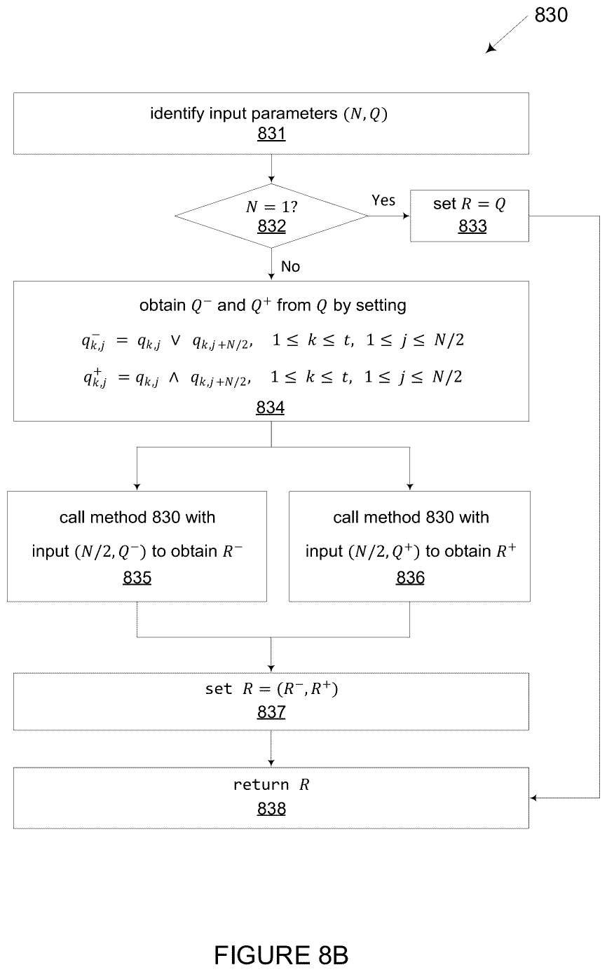

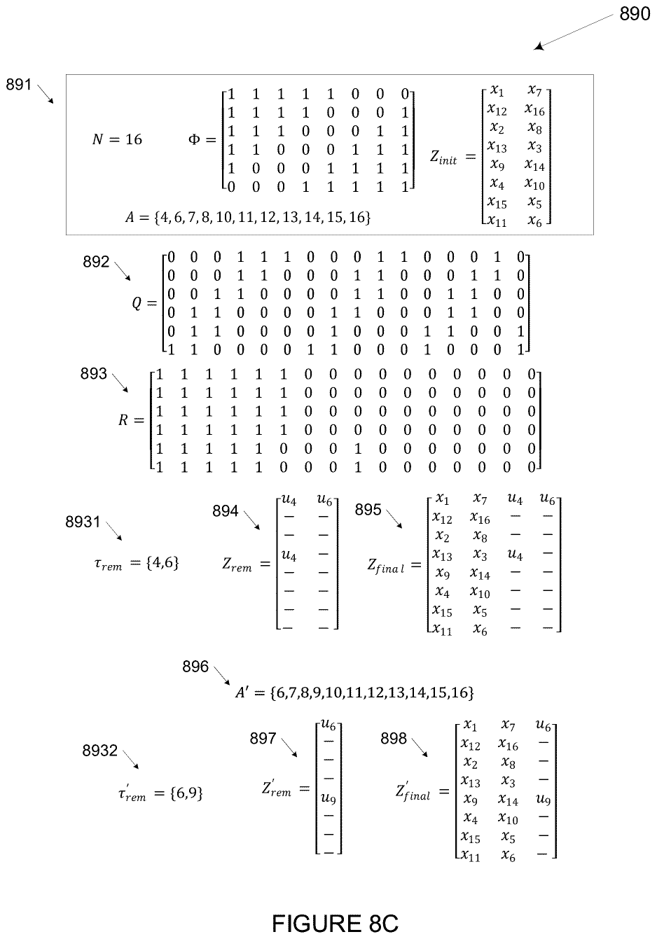

In some embodiments of the present principles, the encoder 320 may compute the data part index set A in real time or, alternatively, retrieve A from a table, such as in the 5G NR polar code bit-selection method. The choice of the data part index set A may, in certain embodiments, depend on zero-error constraints, as illustrated below in connection with FIG. 8C.

In the most basic form of polar coding, the mapping f is an identity mapping, defined as f(d)=d, and the predefined word a is an all-zero word. Thus, the input word formation relation becomes u_{A}=d and u_{A}_{^{c}}=0, where 0 denotes an all-zero word of length |A^{c}|, which applies throughout this document in this context. In the illustrative examples below, this basic form of polar coding is used, as it suffices to present the main ideas with minimal additional complexity. However, the present principles are compatible with other forms of transform input word formation relations known in the prior art. For instance, in some embodiments, a systematic version of polar coding may be employed, where the data word d is inserted directly into the transform output word x, and f(d) is computed by an algorithm. In other embodiments, f(d) may take the form (d, c), where c is a cyclic redundancy check (CRC) computed as a function of d. The CRC c is typically utilized by a list decoder to correctly identify the data word d from among a list of alternatives. In other embodiments, f(d) may involve computing other types of parity bits, such as “dynamically frozen” bits, as used in 5G NR polar coding. In preferred embodiments of the present principles, the mapping d→f(d) is invertible, meaning that d is uniquely determined when f(d) is provided.

To avoid discussing edge cases with limited practical significance, we implicitly assume that 0<K≤|A|≤K+K₀<N, where K₀ is a constant representing the length of an overhead introduced by the transform input formation relation f. This overhead typically includes CRC bits or dynamically-frozen bits. For example, in 5G NR polar codes, K₀ is 11 bits for the uplink and 24 bits for the downlink. By introducing a limit K₀ on the length of the overhead bits, the scope of the present principles is effectively confined to methods based on polar coding.

In preferred embodiments of step 403, the polar encoder 321 computes the transform output word x=uG using a fast polar transform (FPT) method, which computes a polar transform of size N using approximately N log₂ N exclusive- or operations (mod-2 addition) operations. To describe the FPT method, we now refer to the second panel of FIG. 5A. For purposes of illustration, we consider a specific version of the FPT method, which is based on an FPT array P=[p_{i,j}: 1≤i≤n+1, 1≤j≤N] 510, where P has (n+1) rows and N columns for a polar transform of size N=2ⁿ. The ith row of the FPT array P is denoted as pᵢ=(p_{i,1}, P_{,i2}, . . . , p_{i,N}), for 1≤i≤n+1. To compute the polar transform of a transform input word u using the FPT method, the first row of the FPT array is initialized as p₁=u. The remaining rows p₂, p₃, . . . , pₙ₊₁ are computed successively, with the (i+1)th row pᵢ₊₁ obtained from the ith row pᵢ through

$$\frac{N}{2}$$

butterfly operations. The transform output word x is then derived from the last row of the FPT array P by the relation x=pₙ₊₁. We illustrate the butterfly relations using bit-indexing to represent the column indices of the elements in the FPT array P. A column index j∈{1, 2, . . . , N} is replaced by an n-tuple of bits jₙjₙ₋₁ . . . j₁, where

$$j = 1 + {\sum }_{k = 1}^{n} {j}_{k} {2}^{k} 511 .$$

For example, for N=8, the bit-indexed representation of the i th row pᵢ=(p_{i,1}, p_{i,2}, . . . , p_{i,N}=8) is pᵢ=(p_{i,000}, p_{i,001}, . . . >p_{i,111}). In terms of the bit-indexed variables, the relation between the elements of the ith and (i+1)th rows is given by 512:

$${P}_{i + 1 , {j}_{n} {j}_{n - 1} … {j}_{1}} = {\sum }_{{j}_{i}^{′} \geq {j}_{i}} {P}_{i , {j}_{n} {j}_{n - 1} … , {j}_{i + 1} {j}_{i}^{′} {j}_{i - 1} … {j}_{1}} ,$$

where the summation is a mod-2 summation over all j′ᵢ∈{0,1} such that j′ᵢ≥jᵢ. For instance, for N=8, the relations p_{2,000}=p_{1,000}+p_{1,001} and p_{2,004}=p_{1,001} correspond to the butterfly relations p_{2,1}=p_{1,1}+p_{1,2} and p_{2,2}=p_{1,2} between rows 1 and 2. The butterfly relations between successive rows of the FPT array P can be combined to yield an explicit relationship 513:

$${p}_{i + 1 , {j}_{n} {j}_{n - 1} … {j}_{1}} = {\sum }_{{j}_{i}^{′} \geq {j}_{i}} {\sum }_{{j}_{i - 1}^{′} \geq {j}_{i - 1}} … {\sum }_{{j}_{1}^{′} \geq {j}_{1}} {p}_{1 , {j}_{n} {j}_{n - 1} … {j}_{i + 1} {j}_{i}^{′} {j}_{i - 1}^{′} … {j}_{1}^{′}}$$

between the elements of the (i+1)th row pᵢ₊₁ and the elements of the first row p₁, for 1≤i≤n. These relations imply that the FPT array P has N degrees of freedom: the elements of p₁ can be chosen independently, while the remaining elements of P are uniquely determined by p₁. Accordingly, each element of the FPT array P can be interpreted as a “parity-check” on a subset of elements of the transform input word p₁=u.

Referring to the third panel of FIG. 5A, we describe the diversity code array and the corresponding diversity code array formation relation. The specific representations of the diversity code array and the diversity code array formation relation are provided solely for illustrative purposes. The present principles may also be implemented using alternative representations.

The diversity code array is represented as Z=[z_{i,j}: 1≤i≤s, 1≤j≤Mᵢ] 514, where s≥2 denotes the number of rows in Z. Each row zᵢ=(z_{i,1}, z_{i,2}, . . . , z_{i,M}_{ᵢ}) of Z has a length Mᵢ, for 1≤i≤s. The diversity code array formation relation comprises a coordinate mapping h: I_{Z}→Iₚ 515 from the index set I_{Z}={1≤i≤s, 1≤j≤Mᵢ} of Z to the index set Iₚ={1≤i≤n+1, 1≤j≤N} of P. For each (i, j)∈I_{z}, the diversity code array formation relation now associates the (i, j)th element z_{i,j} of Z with an element p_{k,l} of the FPT array P=[ [symbol] : 1≤k≤n+1, 1≤ [symbol] ≤N] by setting z_{i,j}=p_{h(i,j)}.

Based on the foregoing, the encoder 320 implements an encoder mapping d→Z. This mapping defines a “diversity code.” For simplicity, Z is often used as shorthand for the diversity code defined by the encoder mapping d→Z, provided no confusion arises. When referring to a specific diversity code array corresponding to a data word d, we denote it as Z(d).

In preferred embodiments of the present principles the mapping d→Z is divided into two parts. The polar encoder 321 implements a first part

$$d {\to }^{f} u {\to }^{FPT} P .$$

The diversity mapper 322 implements a second part P₀→Z, where P₀={P_{k,l}: (k, l)=h(i, j) for some (i, j)∈I_{z}} represents the subarray of P corresponding to the range of the coordinate mapping h: I_{z}→Iₚ. In the present embodiment, the polar encoder 321 computes the subarray P₀ and makes P₀ accessible to the diversity mapper 322. The elements of the subbarray P₀ form an embodiment of the “plurality of transform variables” referred to in FIG. 4. Broadly, the plurality of transform variables may be any subset of elements chosen from the FPT array P. In some embodiments, the plurality of transform variables comprises the elements of the transform output word x, and each element of the diversity code array Z is associated with an element of the transform output word. In other embodiments, the plurality of transform variables comprises the polar transform output word and at least some elements of the data part of the transform input word, and at least one element of the diversity code array Z is associated with an element of the transform input word. Various alternatives for choosing the plurality of transform variables and associated implementation options, subject to constraints, such as flexibility, backward compatibility, or modularity, are discussed at the end of this disclosure.

An important figure of merit for diversity codes is the code rate. For an encoder mapping d→Z, the code rate is defined as

$$K / {\sum }_{i = 1}^{s} {M}_{i} ,$$

where K denotes the length of the data word d and

$${\sum }_{i = 1}^{s} {M}_{i}$$

denotes the total length of the diversity code array Z. One objective of the present principles is to construct encoder mappings d→Z that achieve high rates while satisfying zero-error constraints.

Finally, we refer to the fourth panel of FIG. 5A to describe the plurality of zero-error constraints. A plurality of zero-error constraint on the diversity code array Z 514 is represented by an array Φ=[Φ_{k,i}: 1≤k≤t, 1≤i≤s] 516, which is referred to as a “zero-error constraints array” or briefly as a “constraints array” in the following. Each row of Φ corresponds to a zero-error constraint; thus, Φ represents t zero-error constraints. The number of columns of Φ equals s, which is the same as the number of rows in Z 514. For 1≤k≤t and 1≤i≤s, an element φ_{k,i} in the kth row of Φ is assigned a value 1 or 0, depending on whether the kth zero-error constraint designates the ith row zᵢ of Z as “observed” or “unobserved,” respectively.

For 1≤k≤t, let [symbol] ={i∈{1, 2, . . . , s}: φ_{k,i}=1} denote the subset of rows of Z 514 identified as observed under the kth zero-error constraint. In a typical embodiment of the present principles, each of the zero-error constraints is associated with a distinct subset of the diversity code array such that the data part is uniquely identifiable from each of the distinct subset of rows. Let Z^{k} denote the array obtained from Z by the formulas 517 and 518. Thus, Z^{k} is obtained from Z 514 by replacing the ith row of Z with null elements (“-”) for each i∉ [symbol] , effectively nullifying (erasing) the information in such rows. The array Z^{k} is a diversity code array, defined by the mapping d→Z^{k}. In the following, Z^{k} is referred to as the “kth observed version of the diversity code array Z.”

For any diversity code d→Z and zero-error constraints array Φ, we say that “the diversity code d→Z uniquely identifies the data word d under Φ” if and only if, for each row index k∈{1, 2, . . . , t} of Φ, the mapping d→Z^{k} is invertible on its range. In other words, d→Z uniquely identifies d under Φ if and only if, for any two distinct data words d and d′, the corresponding kth observed versions Z^{k} (d) and Z^{k} (d′) of Z are distinct for all 1≤k≤t. For brevity, we say that the pair (Φ, Z) satisfies the zero-error constraints if this condition holds. Thus, the notions of “unique identifiability” and “zero-error constraints” are equivalent: a diversity code d→Z uniquely identifies the data word d under Φ if and only if the pair (Φ, Z) satisfies the zero-error constraints. When Φ is fixed or understood from the context, we may also refer to Z as a “zero-error diversity code,” indicating that (Φ, Z) satisfies the zero-error constraints. It is important to note that permuting the elements within any row of a diversity code array does not affect its zero-error property.

Given a zero-error constraints array Φ with s≥2 rows and t≥2 columns, we define a row k of Φ as redundant if there exists a row k′ such that φ_{k′,i}≤φ_{k,i} for all 1≤i≤s. If a row k is redundant, it can be removed from Φ, as Φ already contains a stricter zero-error constraint represented by some other row. An all-zero row in Φ precludes any non-trivial zero-error diversity code. Therefore, the present principles assume that each row of Φ contains at least one “1.” Conversely, an all-one row in Φ is always redundant. To avoid trivial edge cases, the scope of the present principles is restricted to zero-error constraints arrays Φ with s≥2 rows, t≥2 columns, and with no all-zero or all-one rows. In the claims, the phrase “each zero-error constraint designates a non-empty proper subset of the rows as a subset of observed rows” is equivalent to this condition on the zero-error constraints array Φ.

Various alternatives for the plurality of zero-error constraints, stated in terms of the corresponding arrays Φ, are as follows. In some embodiments, the array Φ consists of s≥2 columns and t≥2 rows, where each row contains a fixed number of ones. An important special case is when the rows of Φ comprise all

$$t = ( \begin{matrix}s \\ k\end{matrix} )$$

combinations of k ones and s−k zeros, for some 1≤k≤s. In other embodiments, the array Φ consists of s≥2 columns and t≥2 rows, where each row contains a row-dependent non-zero number of ones, with the ones in each row adjacent to each other. In still other embodiments, the number of ones in each column of the array Φ is proportional to a reliability figure associated with that column.

In general, the zero-error constraints array Φ can be chosen so that each row of Φ corresponds to a zero-error constraint associated with a specific critical failure mode of the channel 330. For example, in some embodiments of the presents principles, the plurality of zero-error constraints can be dynamically determined based on a channel state information available at the transmitter, and the diversity code is then designed or selected from a set of predefined set of choices accordingly.

FIG. 5B illustrates an example 520 of a preferred embodiment of the encoder 320, in accordance with certain aspects of the present principles. The polar encoder 321 in the example 520 employs a basic form of polar coding with parameters (N, K, A), as illustrated in panel 521. The transform input word u is obtained by setting u_{A}=d and u_{A}_{^{c}}=0, also as illustrated in panel 521. The polar transform in the example 520 is implemented using an FPT array P, as shown in the logic diagram 522. In logic diagram 522, the FPT array P is depicted in transposed form, with the rows of P corresponding to columns in the diagram, and signals flowing from left to right. The first column of logic diagram 522 receives the transform input word u through the initialization p₁=u, and at the end of the FPT calculations, the transform output word x is obtained by the relation x=p₄. Logic diagram 522 includes butterfly operations between adjacent layers, such as p_{2,1}=p_{1,1}+p_{1,2} and p_{2,2}=p_{1,2} between layers 1 and 2. Other butterfly relations may be directly inferred from logic diagram 522.

The diversity mapper 322 in the example utilizes the diversity code array formation relation h 523 to obtain the diversity code array 524. The array 523 is a representation that provides a compact and convenient way of specifying the relation h. The (i, j)th entry of array 523 is given by h(i, j), and the code array Z is obtained by setting z_{i,j}=p_{h(i,j)} for each (i, j)∈I_{z}.

The plurality of zero-error constraints in the example 520 is represented by the array Φ 525. The array Φ 525 comprises s=4 columns, which matches the number of rows of the diversity code array Z 524. There are t=6 rows in the array Φ 525, each corresponding to a zero-error constraint. These rows cover all

$$( \begin{matrix}s \\ 2\end{matrix} ) = ( \begin{matrix}4 \\ 2\end{matrix} ) = 6$$

combinations of nullifying two specific rows of the code array Z 524 while leaving the other two rows of Z intact.

In the example 520, there are t=6 observed versions of Z 524, denoted as Z^{k} 526-k for 1≤k≤t=6. For example, the first row of Φ represents a zero-error constraint that nullifies the third and fourth rows of Z 524, yielding the array Z₁ 526-1. The same logic applies to each row of Φ, with each row defining a constraint that nullifies two specific rows of Z 524 to yield the corresponding observed version Z^{k} 526-k, for 1≤k≤6.

This concludes the description of example 520. At this point, the question arises as to whether the pair (Φ, Z) in this example satisfies the zero-error constraints. We first provide a heuristic answer to this question for the specific case of example 520, followed by a general method for determining whether any given pair (Φ, Z) satisfies the zero-error constraints.

The question of unique identifiability under the kth zero-error constraint is equivalent to determining whether the transform equation x=uG has a unique solution for u_{A}=d given the observations available in Z^{k} and the knowledge that u_{A}_{^{c}}=0. For the first observed version Z₁ 526-1, the observed variables are x₁, x₂, x₃, x₄, u₄, and u₆. Expressed in terms of the unknows d=(d₁, d₂, d₃, d₄), the observed variables can be written as a system of linear equations:

$$( {x}_{1} , {x}_{2} , {x}_{3} , {x}_{4} , {u}_{4} , {u}_{6} ) = ( {d}_{1} , {d}_{2} , {d}_{3} , {d}_{4} ) [ \begin{matrix}1 & 1 & 1 & 1 & 1 & 0 \\ 1 & 1 & 0 & 0 & 0 & 1 \\ 1 & 0 & 1 & 0 & 0 & 0 \\ 1 & 1 & 1 & 1 & 0 & 0\end{matrix} ] .$$

This system of equations can be inferred from the relations u_{A}=d and u_{A}_{^{c}}=0 in panel 521, and the logic diagram 522 of the FPT array P. Since the coefficient matrix defining this system of equations has full rank, the data word d is uniquely identifiable under the first zero-error constraint. A similar analysis shows that the data word d is uniquely identifiable under the kth zero-error constraint, for any 1≤k≤6. Therefore, the pair (Φ, Z) in example 520 satisfies the zero-error constraints. Building on the ideas in this example, a general method for checking if a pair (Φ, Z) satisfies the zero-error constraints is given next.

FIG. 5C is a flowchart of a zero-error check method 530 for checking if a diversity code satisfies a plurality of zero-error constraints in accordance with certain aspects of the present principles. Zero-error check method 530 is an example of a “zero-error check method” that operates under the assumption that, in the encoding step 402, the transform input word u is obtained from the data word d=(d₁, d₂, . . . , d_{K}) by setting u_{A}=d and u_{A}_{^{c}}=a, where A is a data part index set and α is a fixed word.

Step 531 of zero-error check method 530 identifies the input parameters (N, A, Φ, Z) where N is a polar transform size, A is a data part index set, Φ is a zero-error constraints array, and Z is a diversity code array. According to the diversity coding method of FIG. 5B, the mapping d→Z from data words d to diversity code arrays Z(d) comprises a sequence of mappings d→u→P→Z, where each mapping in the sequence is linear, except for the first mapping d→u, which is affine when the fixed word α is non-zero. Consequently, the overall mapping d→Z can be expressed in canonical form as an affine mapping

$$Z = {\sum }_{ℓ = I}^{K} {d}_{ℓ} {D}_{ℓ} + {D}_{0}$$

where D₀, D₁, . . . , D_{K} are a collection of “basis arrays” with the same dimensions as the diversity code array Z. The array D₀ equals zero if the fixed word a equals zero. Using the vectorization operation on arrays (as defined above), this relation can also be rewritten as

$$v e c ( Z ) = {\sum }_{ℓ = 1}^{K} {d}_{ℓ} v e c ( {D}_{ℓ} ) + v e c ( {D}_{0} ) ,$$

which, in turn, can be expressed as vec(Z)=dΔ+vec(D₀) where Δ=[ [symbol] : 1≤ [symbol] ≤K, 1≤j≤M₁+M₂+ . . . +Mₛ] is a matrix with K rows, and the [symbol] th row is given by vec( [symbol] ). We refer to the matrix Δ as a “generator matrix” for the diversity code array Z.

Starting from the canonical form

$$Z = {\sum }_{ℓ = 1}^{K} {d}_{ℓ} {D}_{ℓ} + {D}_{0} ,$$

we obtain a corresponding canonical form

$${Z}^{k} = {\sum }_{ℓ = 1}^{K} {d}_{ℓ} {D}_{ℓ}^{k} + {D}_{0}^{k} , where {D}_{ℓ}^{k}$$

is the array that is obtained from [symbol] in the same manner that Z^{k} is obtained from Z. In other words,

$${D}_{ℓ}^{k}$$

denotes the array obtained from [symbol] by replacing the elements in the ith row of [symbol] with null elements (“-”) for each i∈ [symbol] . Applying the vectorization operation, the expression

$$v e c ( {Z}^{k} ) = {\sum }_{ℓ = 1}^{K} {d}_{ℓ} v e c ( {D}_{ℓ}^{k} ) + v e c ( {D}_{0}^{k} )$$

is obtained. This can be written as

$$v e c ( {Z}^{k} ) = d {Δ}^{k} + v e c ( {D}_{0}^{k} ) ,$$

where Δ^{k} is the matrix whose [symbol] th row is given by vec ( [symbol] ), for 1≤ [symbol] ≤K. The matrix Δ^{k} serves as a generator matrix for Z^{k}, and we refer to Δ^{k} as the kth reduced generator matrix. The kth reduced generator matrix Δ^{k} can be obtained directly from the original generator matrix Δ by deleting the columns of Δ that correspond to unavailable observations under the kth zero-error constraint.

In terms of the present formulation, the unique identifiability condition can be stated as “if d′≠d, then Z^{k} (d)≠^{k} (d′) for all 1≤k≤t,” which in turn can be stated as “if d′≠d, then dΔ^{k}≠d′Δ^{k} for all 1≤k≤t.” This leads to the following rank-criterion: a pair (Φ, Z) satisfies the zero-error constraints if and only if rank (Δ^{k})=K for all 1≤k≤t. This rank criterion forms the basis of the remaining steps in zero-error check method 530.

Step 532 obtains the basis arrays Dₗ, 0≤ [symbol] ≤K. Step 533 obtains the generator matrix Δ and the reduced generator matrices Δ¹, Δ², . . . , Δ^{t}, where t is the number of rows of Φ (which equals the number of constraints). Step 534 computes the ranks rₖ=rank (Δ^{k}) for 1≤k≤t. Step 535 declares that (Φ, Z) satisfies the zero-error constraints if rₖ=|A| for all k∈{1, 2, . . . , t}; otherwise, step 535 declares that (Φ, Z) does not satisfy the zero-error constraints if there exists a k∈{1, 2, . . . , t} such that rₖ<|A|. This concludes the description of the zero-error check method 530.

Zero-error check method 530 provides an algorithmic definition of the zero-error constraints for a specific embodiment of the present principles. One skilled in the art will readily understand how to adapt zero-error check method 530 to more general embodiments where the polar encoder 321 employs, in encoding step 402 of polar encoding, a transform input word formation relation f: d→u that incorporates CRC or distributed-parity computations. FIGS. 5D through 5G illustrate the zero-error check method 530 with several examples.

FIG. 5D illustrates a first example 550 of the zero-error check method 530 depicted in FIG. 5C. In example 550, the input parameters (N, A, Q, Z₁) are as shown in panel 551. The data word d has a length K=|A|=4, the polar transform has a size N=8, the diversity code array Z=Z₁ comprises s=4 rows, and the zero-error constraints array Φ includes all t=6 combinations of nullifying two rows out of four. The diversity code array Z₁ consists solely of the elements of the transform output word x=(x₁, x₂, . . . , x₈), which are arranged in Z₁ in accordance with the balanced row-major order, as defined above. The basis arrays D₁, D₂, . . . , D_{K} are displayed in panel 552. The generator matrix Δ and the reduced generator matrices Δ¹, Δ², . . . , Δ^{t} are displayed in panel 553. The ranks rₖ=rank (Δ^{k}), for 1≤k≤t, are shown in panel 554. The pair (Φ, Z₁) does not satisfy the zero-error constraints since the rank condition (requiring all ranks to equal K=4) fails to hold.

FIG. 5E illustrates a second example 560 of the zero-error check method 530 depicted in FIG. 5C. The second example 560 differs from the first example 550 in the ordering of the elements in the diversity code array: Z₂ is a permuted version of Z₁. In example 560, a permutation π is applied to the transform output word x, yielding π·x=(x₁, x₅, x₈, x₂, x₆, x₃, x₇, x₄). The array Z₂ with s=4 rows is constructed from the permuted word π·x using the balanced row-major order. The permutation π is based on the 5G NR triangular channel interleaving method. As shown in panel 564, the ranks rₖ=rank (Δ^{k}), for 1≤k≤t, in example 560 are all equal to K=4. Consequently, the pair (Φ, Z₂) satisfies the zero-error constraints. Example 560 highlights the importance of a carefully selected interleaver on the zero-error properties of a diversity code array. The diversity code array Z₂ has a code rate 1/2.

It can be shown that the code rate 1/2 is the highest possible code rate achievable by any diversity code (including non-linear codes) for transmitting K=4 bits of data under the zero-error constraints in this example. The code array Z₂ happens to coincide with an extended Reed-Solomon code over GF(4) and is an MDS code. In general, the present principles do not yield MDS codes; however, they compensate for this rate deficiency by offering seamless integration with polar codes, enabling low-complexity encoding and soft-decision decoding.

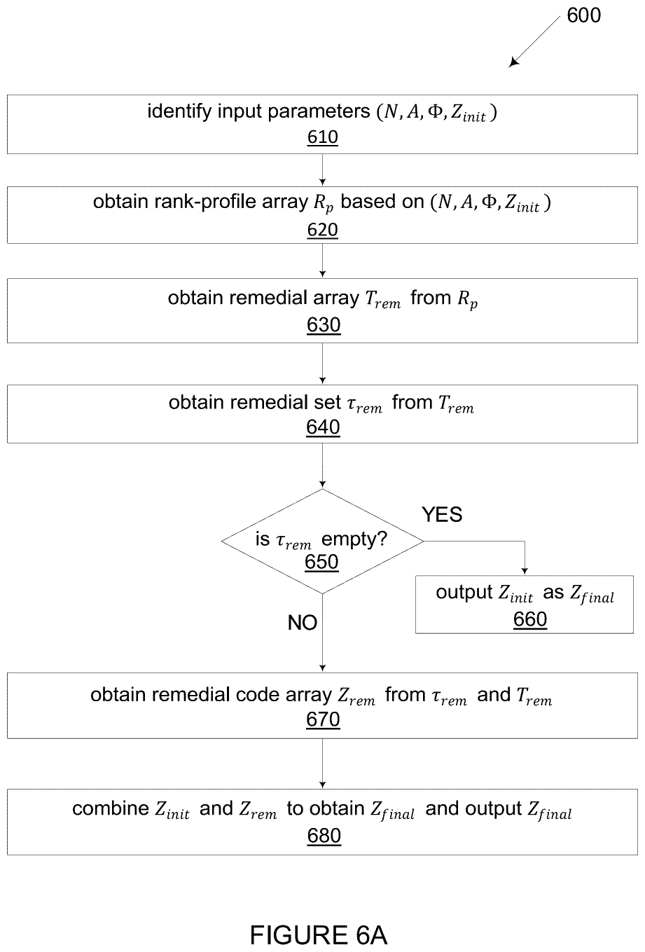

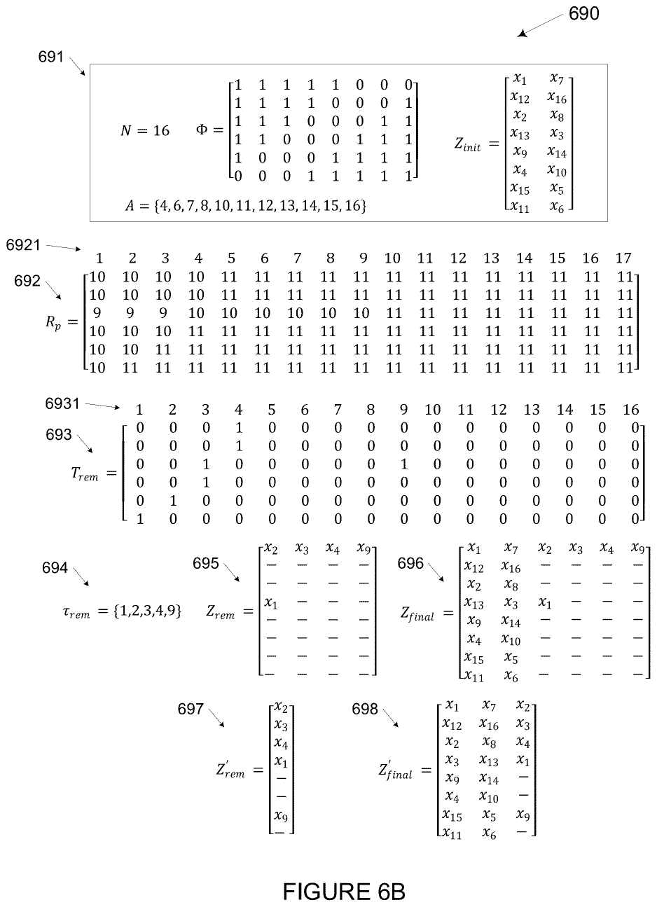

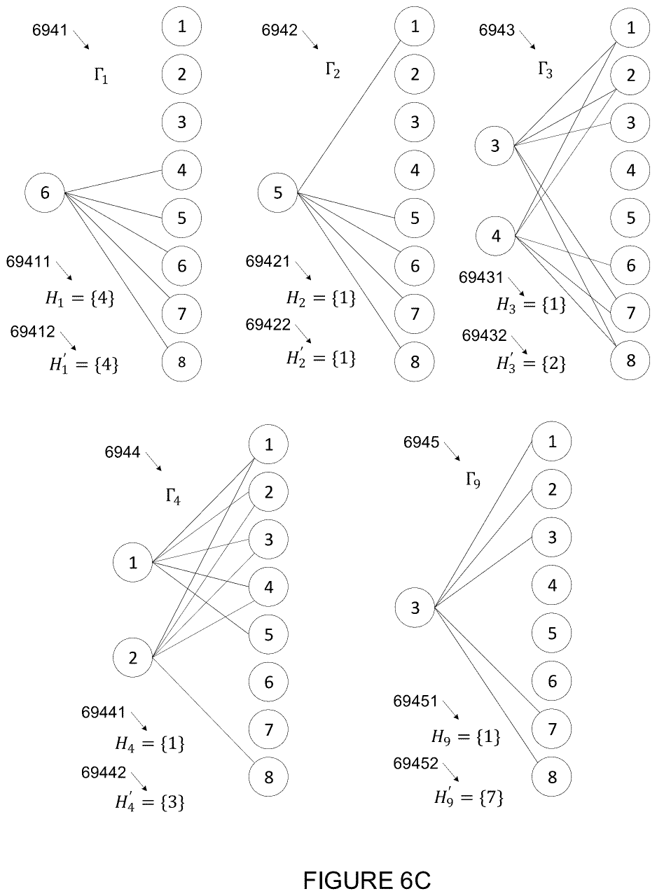

FIG. 5F illustrates a third example 570 of the zero-error check method 530 depicted in FIG. 5C. The diversity code array Z₃ in example 570 is derived from the diversity code array Z₁ of example 550 using a zero-error diversity code array construction method referred to as the “ML-x” method, which will be presented in connection with FIG. 6A. The ML-x method is a method introduced in the present disclosure and augments a given diversity code array with additional transmissions, if necessary, to obtain a zero-error diversity code array. These additional transmissions in the ML-x method are chosen from the elements of the transform output word x. The “ML” in the name of the method signifies that the ML-x method guarantees zero-error decoding under maximum likelihood (ML) decoding, which represents the optimal decoding method. In example 570, there are four additional transmissions: x₃ and x₅ in the first row, x₁ in the second and third rows. The pair (Φ, Z₃) satisfies the zero-error constraints as shown by the ranks 574, and has a code rate 4/12.

FIG. 5G illustrates a fourth example 580 of the zero-error check method 530 depicted in FIG. 5C. The diversity code array Z₄ in example 580 is obtained from the diversity code array Z₁ of example 550 using a zero-error diversity code array construction method referred to as the “SC-u” method, which will be presented in connection with FIG. 8A. The SC-u method augments a given diversity code array with additional transmissions, if necessary, to obtain a zero-error diversity code array. The additional transmissions in the SC-u method are chosen from the elements of the transform input word u. The “SC” in the name of the method signifies that the SC-u method guarantees zero-error decoding even under successive cancellation (SC) decoding, which is a suboptimal decoding method. In example 580, there are four additional transmissions: u₄ and u₆ in the first row, u₆ in the second row, and u₄ in the third row. The pair (Φ, Z₄) satisfies the zero-error constraints as shown by the ranks 584, and has a code rate 4/12.

A trivial method of constructing zero-error diversity codes is to repeat the data word d in each row of Z, resulting in a zero-error diversity code array with rate 1/s. More efficient solutions based on repetition can be obtained by solving a combinatorial problem. Let the zero-error constraints array be given by Φ=[φₖᵢ: 1≤k≤t, 1≤i≤s]. Consider subsets of column indices H⊂{1, 2 . . . , s} that satisfy the condition that, for each k∈{1, 2, . . . , t}, there exists an index i∈H such that φ_{k,i}=1. A set H satisfying this property is called a hitting set in Φ. The transversal number of Φ, denoted τ(Φ), is defined as the minimum size of a hitting set H. Given a hitting H with |H|=τ(Φ), an encoder mapping d→Z can be defined by setting the ith row zᵢ of Z as zᵢ=d if i∈H, and leaving zᵢ an all-null row if i∉H. The pair (Φ, Z) satisfies the zero-error constraints and achieves a code rate 1/τ (Φ). In general computing τ(Φ) is an NP-hard problem; however, for zero-error constraints arrays Φ with specific structures or small sizes, τ(Φ) can be determined using known formulas or computed feasibly through exhaustive search. In the following, the rate 1/τ (Φ) is used as a benchmark to assess whether the methods presented below can achieve code rates that significantly exceed those attainable through simple repetition techniques. In preferred embodiments of the present principles, the product of the length of the data word and the transversal number of the plurality of constraints is less than the total number of elements in the diversity code array, expressed as:

$$K τ ( Φ ) < {\sum }_{i = 1}^{s} {M}_{i} .$$

For example, zero-error constraints array Φ 525 in the examples of FIGS. 5D through 5G has a transversal number τ(Φ)=3, yielding a benchmark rate of 1/3. The zero-error diversity code Z₂ in FIG. 5E has a rate 1/2, which significantly exceeds the benchmark code rate. On the other hand, the zero-error diversity code Z₃ in FIGS. 5F and Z₄ in FIG. 5G have rates 1/3, which match the benchmark code rate. Although, Z₃ and Z₄ do not outperform the repetition-based zero-error diversity coding schemes in terms of code rate, they provide better protection against additiveve noise thanks to the parity bits they contain, as opposed to raw data bits.

FIGS. 6A to 6C, 7A to 7E, and 8A to 8C present three heuristic methods, called ML-x, SC-x, and SC-u, for zero-error diversity code construction. These methods receive a set of input parameters (N, A, Φ, Zᵢₙᵢₜ), where N is the polar transform size, A is the data part index set, Φ is the zero-error constraints array, and Zᵢₙᵢₜ is an initial diversity code array.

The initial diversity code array Zᵢₙᵢₜ may be an arbitrary array with s rows, one option being an empty array. In some preferred embodiments, each element of the initial diversity code array Zᵢₙᵢₜ is associated with an element of a polar code word, where the polar code word may be produced by a legacy polar encoder, for example, a 5G NR polar encoder. The present principles are compatible with a wide variety of legacy polar encoders. For example, the polar encoder 321 may be a legacy polar encoder configured to generate a polar code word w=(w₁, w₂, . . . , w_{F}) from the transform output word x through a polar code word formation relation, which in general may depend on several parameters, such as target code word length, link direction (uplink/downlink), etc. In legacy systems, such parameters are typically supplied by a higher-layer protocol. Given all relevant parameters for specifying the polar code word formation relation, the legacy polar encoder may obtain the polar code word by a mapping gₚₒₗₐᵣ: I_{w}→Iₓ from the index set of w to the index set of x, where the mapping gₚₒₗₐᵣ associates each element of w with an element of x via wᵢ=X_{g}_{ₚₒₗₐᵣ}(i), for 1≤i≤F. This framework is flexible enough to encompass prior-art rate-adaptive polar coding methods, including shortening, puncturing, and repetition methods as used in 5G NR polar codes. Once w is obtained by the legacy polar encoder, the diversity mapper 322 can obtain Zᵢₙᵢₜ from w using any method of copying w into Zᵢₙᵢₜ. For example, w can be copied into Zᵢₙᵢₜ following the balanced row-major order, defined above.

Given the initial diversity code array Zᵢₙᵢₜ, the ML-x, SC-x, and SC-u methods apply specific procedures to construct a remedial diversity code array Zᵣₑₘ so that when Zᵣₑₘ is appended to Zᵢₙᵢₜ a final diversity code array Z_{final} is obtained such that (Φ, Z_{final}) satisfies the zero-error constraints. The ML-x and SC-x methods select the elements of Zᵣₑₘ from the transform output word x, while the SC-u method selects the elements of Zᵣₑₘ from the transform input word u. The ML-x method guarantees that (Φ, Z_{final}) satisfies the zero-error constraints under maximum-likelihood (ML) decoding, but not under any other suboptimal decoding method, such as successive-cancellation (SC) decoding. In contrast, SC-x and SC-u methods ensure that (Φ, Z_{final}) satisfies the zero-error constraints under SC decoding or some modified version of SC decoding.

All three zero-error diversity code array construction methods rely on the concepts of transmission and reception sets. For a diversity code array Z=[z_{i,j}: 1≤i≤s, 1≤j≤Mᵢ], the transmission sets C₁, C₂, . . . , Cₛ of Z are defined as Cⱼ={ [symbol] ∈Iₓ:z_{j,m}=xₗ for some 1≤m≤Mᵢ}, for 1≤j≤s. The jth transmission set Cⱼ represents the set of indices l of elements xₗ in the transform output word x that appear in the jth row of Z. The reception sets B₁, B₂, . . . , Bₜ for the pair (Φ, Z) are defined as Bₖ=U_{j:φk,j}=1 C; for 1≤k≤t. The kth reception set Bₖ represents the set of indices l of elements xₗ in x that appear in one of the rows of Z that is not nullified by the kth zero-error constraint.

FIG. 6A is a flowchart 600 illustrating the steps of the ML-x method for constructing zero-error diversity codes in accordance with certain aspects of the present principles. The ML-x method takes as input a set of parameters (N, A, Φ, Zᵢₙᵢₜ) and produces a diversity code d→Z_{final} as output, where the pair (Φ, Z_{final}) is guaranteed to satisfy the zero-error constraints under ML decoding. The details of each step of the ML-x method are provided below.

Step 610 of the ML-x method identifies the input parameters (N, A, Φ, Zᵢₙᵢₜ), where N is a polar transform size, A is a data part index set, Φ is a zero-error constraints array, and d→Zᵢₙᵢₜ is an initial diversity code.

Step 620 obtains a rank-profile array Rₚ from the parameters (N, A, Φ, Zᵢₙᵢₜ), where Rₚ is a t×(N+1) array with elements defined as (Rₚ)_{k,j}=rank (G_{A,B}_{ₖ}_{U[1,i j-1]})), 1≤k≤t, 1≤j≤N+1, where B₁, B₂, . . . , Bₜ are the reception sets for the pair (Φ, Zᵢₙᵢₜ). Here, G_{A,B}_{ₖ}_{U [1,j-1]} denotes the submatrix of the polar transform matrix G=F^{⊗log2N}, comprising the elements of G with row indices in A and column indices in Bₖ U [1, j−1]. The set [1, j−1] is defined as the empty set when j=1, and [1, j−1]={1, 2, . . . , j−1} for 2≤j≤N+1. The rank-profile array Rₚ has the property that entries within any given row of Rₚ form a non-increasing sequence from left to right, with adjacent entries differing by at most one. This property follows from the fact that the rank of a matrix remains the same or decreases by at most one when a column is removed.

Step 630 obtains a remedial array Tᵣₑₘ from Rₚ, where the remedial array Tᵣₑₘ is defined as a t×N array with elements (Tᵣₑₘ)_{k,j}=(Rₚ)_{k,j}−(Rₚ)_{k,j+1}, 1≤k≤t, 1≤j≤N. The elements (Tᵣₑₘ)_{k,j} are either 0 or 1 since the entries in a given row of Rₚ are non-increasing and adjacent entries can differ by at most one. Having (Tᵣₑₘ)_{k,j} equal to 1 signifies two points: (1) the jth element xⱼ of the transform output word x is unobserved under the kth zero-error constraint, meaning j∈ [symbol] ; and (2) accessing the value of xⱼ is equivalent to obtaining one additional linearly independent equation in the ML decoding process under the kth zero-error constraint. In the following, x is called “rank-critical under the kth zero-error constraint” if (Tᵣₑₘ)_{k,j} equals 1.

Step 640 obtains a remedial set τᵣₑₘ from the remedial array Tᵣₑₘ by computing the column sums

$${σ}_{j} = {\sum }_{k = 1}^{t} {( {T}_{rem} )}_{k , j} of {T}_{rem} ,$$

for 1≤j≤N, and setting τᵣₑₘ={j∈{1, 2, . . . , N}: σⱼ>0}. The elements of τᵣₑₘ is a list of indices j of rank-critical elements x; of the transform output word x.

Step 650 checks if τᵣₑₘ is empty, and moves to step 660 or step 670 if the answer is YES or NO, respectively.

Step 660 outputs Z_{final}=Zᵢₙᵢₜ, with the guarantee that (Φ, Z_{final}) satisfies the zero-error constraints.

Step 670 obtains a remedial diversity code array Zᵣₑₘ from (τᵣₑₘ, Tᵣₑₘ) by solving an instance of a node covering problem in a bipartite graph for each element of τᵣₑₘ. The instance corresponding to j∈τᵣₑₘ is defined in terms of a bipartite graph Γⱼ consisting of a set of left-side nodes [symbol] , a set of right-side nodes [symbol] (which is independent of j), and edges connecting specific pairs of left- and right-side nodes. The set of left-side nodes is defined as Lⱼ={k∈{1, 2, . . . , t}: (Tᵣₑₘ)_{k,j}=1}. Thus, Lⱼ consists of the constraint indices k∈{1, 2, . . . , t} for which the element xⱼ of the transform output word x is rank-critical. The set of right-side nodes is defined as [symbol] ={1, 2, . . . , s}, and contains one node for each row index i∈{1, 2, . . . , s}. The bipartite graph Γᵢ contains an edge (k, i) between a left-side node k∈Lⱼ and a right-side node i∈ [symbol] if and only if φ_{k,i}=1. A subset H⊂ [symbol] of right-side nodes is called a “node-cover” if for each left-side node k∈Lⱼ there exists a right side node i∈Hⱼ such that (k, i) is an edge in Γⱼ. Given a node-cover Hⱼ, step 670 constructs the remedial diversity code array Zᵣₑₘ as an array with s rows, where the ith row of Zᵣₑₘ contains the element xⱼ if and only if j∈τᵣₑₘ and i∈Hⱼ, for 1≤j≤N and 1≤i≤s. Thus, the rows of Zᵣₑₘ comprise elements x; with j∈Tᵣₑₘ; each such element x appears in at least one row of Zᵣₑₘ; and, certain rows of Zᵣₑₘ may remain null.

It is known that the finding a node-cover with minimum size is an NP-hard problem in general. It is also known that the node-cover problem in a bipartitite graph is equivalent to a suitably defined hitting-set a problem. There exist various heuristic methods for finding suboptimal solutions to the node-cover and hitting-set problems. The present principles can be implemented using any such heuristic method from prior art. In the examples below, we employ a greedy heuristic for finding a node-cover.

Step 680 augments the initial diversity code array Zᵢₙᵢₜ with the remedial diversity code array Zᵣₑₘ to obtain a final diversity code array Z_{final}. Let C_{init,i} and C_{rem,i} denote the ith transmission sets of Zᵢₙᵢₜ and Zᵣₑₘ, respectively, for 1≤i≤s. The final diversity code array Z_{final} is then defined such that its ith transmission set is given by C_{final,i}=C_{init,i} U C_{rem,i}, for 1≤i≤s. The pair (Φ, Z_{final}) is guaranteed to satisfy the zero-error constraints under ML decoding. This completes the description of the ML-x method. We now turn to an example that demonstrates the ML-x method.

FIGS. 6B and 6C illustrate an example 690 of the ML-x method depicted in FIG. 6A. In the example 690, step 610 identifies the input parameters as (N, A, Φ, Zᵢₙᵢₜ) 691. Step 620 obtains the rank-profile array as Rₚ 692. Step 630 obtains the remedial array Tᵣₑₘ 693 from Rₚ 692. Step 640 computes the remedial set τᵣₑₘ 694 by picking the column indices k of Tᵣₑₘ 693 for which the column sums are positive. The labels 6921 and 6931 serve as a visual aids for identifying the column indices of Rₚ 692 and Tᵣₑₘ 693, respectively, with no other significance. Step 650 identifies that τᵣₑₘ 694 is non-empty and proceeds to step 670.

Step 670 sets up an instance of the node-cover problem for each element of τᵣₑₘ 694, with the instance corresponding to j∈τᵣₑₘ represented by a bipartite graph Γⱼ, as illustrated by the graphs Γ₁ 6941, Γ₂ 6942, Γ₃ 6943, Γ₄ 6944, and Γ₉ 6945. In the example 690, the set of left-side nodes are given as follows: [symbol] ={6}, [symbol] ={5}, [symbol] ={3,4}, [symbol] ={1, 2}, and [symbol] ={3}. The set of right-side nodes are given by [symbol] ={1, 2, . . . , s=8} for all j∈τᵣₑₘ 694.

Step 670 solves the node-cover problems 6941-6945 using a first-fit heuristic to obtain a set of solutions, represented by H₁ 69411, H₂ 69421, H₃ 69431, H₄ 69441, and H₉ 69451, which collectively yield the remedial diversity code array Zᵣₑₘ 695. Optionally, step 670 may use a balanced-fit heuristic to obtain a alternate set of solutions to the node-cover problems 6941-6945, represented by

$${H}_{1}^{′} 69412 , {H}_{2}^{′} 69422 , {H}_{3}^{′} 69432 , {H}_{4}^{′} 69442 , and {H}_{5}^{′} 69452 ,$$

which result in the remedial diversity code array

$${Z}_{rem}^{′} 697.$$

The first-fit heuristic solves the hitting set problem using a greedy approach that prioritizes right-side nodes with larger edge degrees, breaking ties in favor of nodes with smaller indices. The balanced-fit heuristic, also a greedy procedure based on edge degrees, differs in that it resolves ties by balancing the number of times a right-side node i∈{1, 2, . . . , s} is used across the collection of hitting sets {Hⱼ: j∈τᵣₑₘ}.

Step 680 obtains the final diversity code array Z_{final} 696 by augmenting the initial diversity code array Zᵢₙᵢₜ in 691 with the remedial diversity code array Zᵣₑₘ 695. Optionally, step 680 may obtain an alternative final diversity code array

$${Z}_{final}^{′} 698$$

By augmenting the initial diversity code array Zᵢₙᵢₜ in 691 with the remedial diversity code array

$${Z}_{rem}^{′} 697.$$

By construction, both final diversity codes d→Z_{final} 696 and

$$d \to {Z}_{final}^{′} 698$$

are guaranteed to satisfy the zero-error constraints.

The code rates for both Z_{final} 696 and

$${Z}_{final}^{′} 698$$

are 11/21. The transversal number of zero-error constraints array Φ 690 is τ(Φ)=2, which indicates that, under the zero-error constraints Φ, the best rate achievable by simple repetition schemes is 1/2. Thus, the zero-error codes constructed by the ML-x method in this example achieve rates slightly above the benchmark code rate.

In FIGS. 6A to 6C, we focused on the construction of zero-error diversity codes under ML decoding. Although ML decoding is in general too complex to implement in practice, for polar codes its performance can be closely approximated using SCL decoders with sufficiently large list sizes. Next, we discuss the construction of zero-error diversity codes under SC decoding. Compared to ML zero-error diversity codes, SC zero-error diversity codes offer a less efficient solution in terms of code rate but a more practical alternative with a lower decoding complexity.

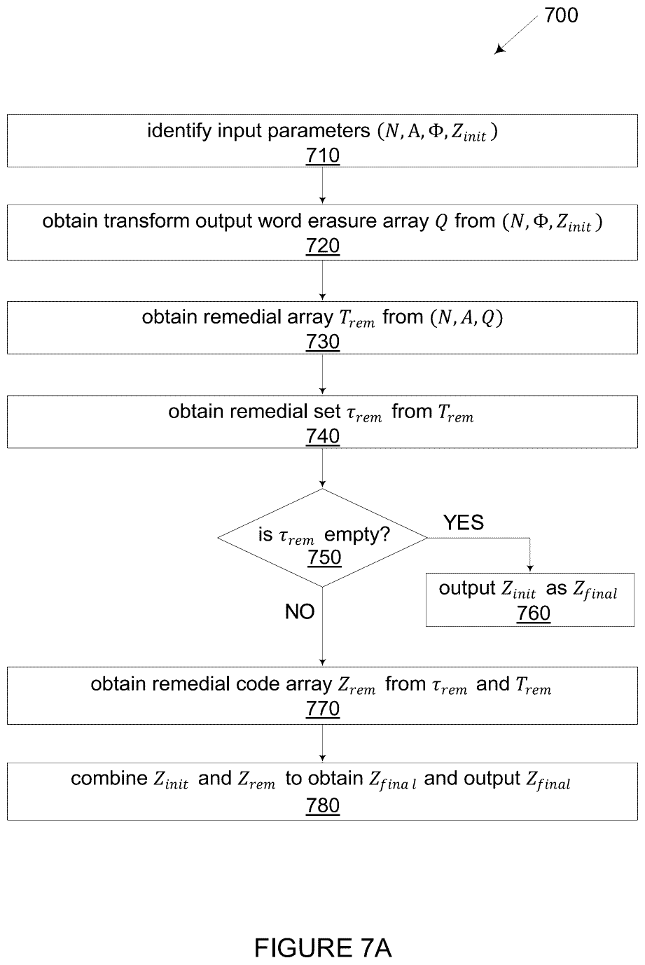

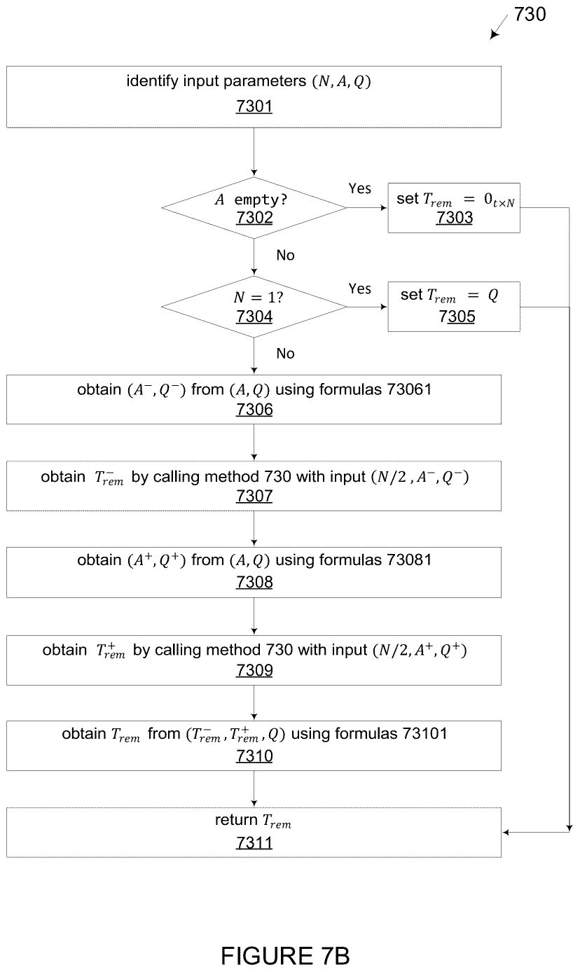

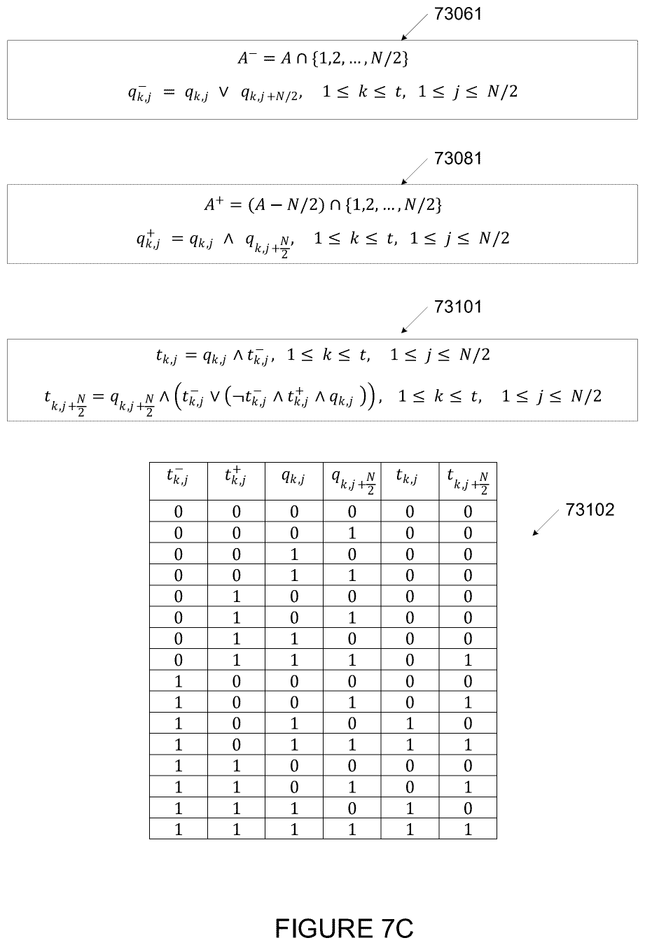

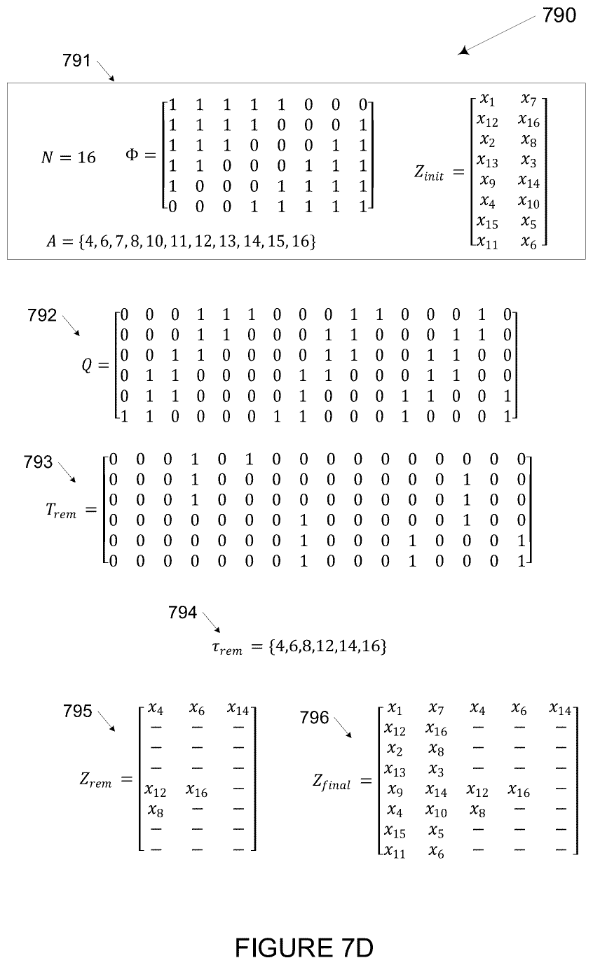

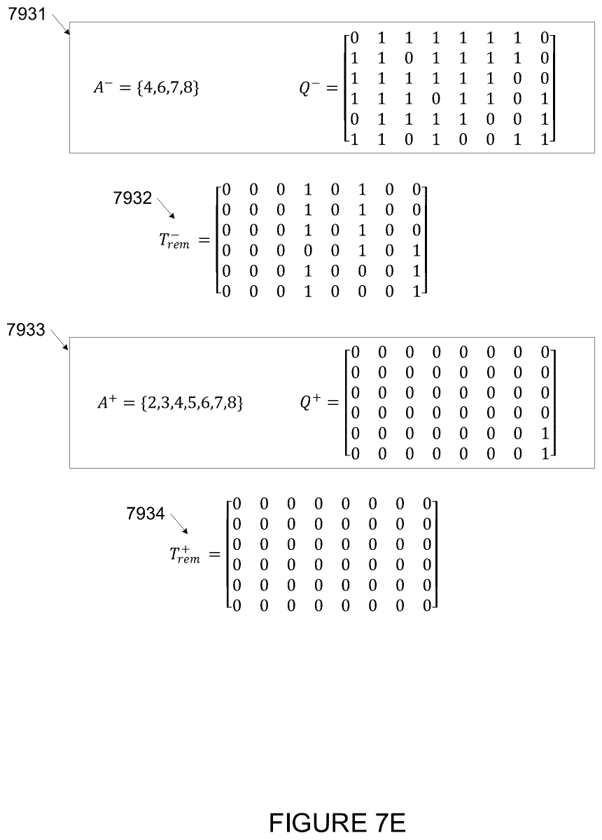

FIG. 7A is a flowchart 700 illustrating the steps of the SC-x method for constructing zero-error diversity codes in accordance with certain aspects of the present principles. The SC-x method takes as input a set of parameters (N, A, Φ, Zᵢₙᵢₜ) and produces a diversity code d→Z_{final} as output, where the pair (Φ, Z_{final}) is guaranteed to satisfy the zero-error constraints under SC decoding. The details of each step of the SC-x method are provided below.

Step 710 identifies the input parameters (N, A, Φ, Zᵢₙᵢₜ), wherein N is a polar transform size, A is a data part index set, Φ is a zero-error constraints array, and d→Zᵢₙᵢₜ is an initial diversity code.

Step 720 obtains a transform output word erasure array Q=[q_{k,j}: 1≤k≤t, 1≤j≤N] from the parameters (N, Φ, Zᵢₙᵢₜ) by setting q_{k,j} to 0 if j∈Bₖ, and to 1 if j∉Bₖ, where B₁, B₂, . . . , Bₜ are the reception sets for the pair (Φ, Zᵢₙᵢₜ). In other words, q_{k,j} equals 1 if and only if the jth element x; of the transform output word x is erased under the kth zero-error constraint, for 1≤k≤t and 1≤j≤N. Alternatively, q_{k,j} equals 1 if and only if xⱼ does not appear in any row of the kth observed version

$${Z}_{init}^{k}$$

of the initial diversity code array Zᵢₙᵢₜ, for 1≤k≤t and 1≤j≤N. Under the kth zero-error constraint, an SC decoder observes the portion x_{B}_{ₖ} of the transform output word x, while the remaining part of x gets nullified or erased. The kth row of the output word erasure array Q serves as an indicator vector that specifies which elements of the transform output word x are erased under the kth zero-error constraint, for 1≤k≤t.

Step 730 obtains a remedial array Tᵣₑₘ from the parameters (N, A, Q). Step 730 comprises steps 7301-7311 as illustrated in FIG. 7B, which involve calling step 730 recursively. Step 7301 identifies the input parameters (N, A, Q). Step 7302 selects the next step as 7303 or 7304 depending on whether the data part index set A is empty or not, respectively. Step 7303 sets the remedial array Tᵣₑₘ to a t×N array of all zeros 0_{t×N} and moves to step 7311. Step 7304 selects the next step as 7305 or 7306 depending on whether the polar transform size N equals one or not. Step 7305 sets Tᵣₑₘ to Q and moves to step 7311. Step 7306 obtains a left-side pair of parameters (A⁻, Q⁻) from (A, Q) using formulas 73061 illustrated in FIG. 7C, wherein

$${q}_{k , j}^{-}$$

denotes the (k, j)th entry of Q⁻ for 1≤k≤t, 1≤j≤N/2. Step 7307 obtains a left-side remedial array

$${T}_{rem}^{-}$$

by a recursive call to step 730 using the left-side input parameters (N/2, A⁻, Q⁻). Step 7308 obtains a right-side pair of parameters (A⁺, Q⁺) from (A, Q) by using formulas 73081 illustrated in FIG. 7C, wherein the notation “(A−N/2)” denotes the set

$$\{ j : j + \frac{N}{2} ∈ A \} ,$$

which is obtained by subtracting N/2 from each element of A, and wherein

$${q}_{k , j}^{+}$$

denotes the (k,j)th entry of Q⁺ and

$${t}_{k , j}^{-}$$

denotes the (k,j)th entry of

$${T}_{rem}^{-}$$

for 1≤k≤t, 1≤j≤N/2. Step 7309 obtains a right-side remedial array

$${T}_{rem}^{+}$$

by a recursive can to step 730 using the right-side input parameters (N/2, A⁺, Q⁺). Step 7310 obtains the remedial array Tᵣₑₘ from

$${T}_{rem}^{-} and {T}_{rem}^{+}$$

using formulas 73101 illustrated in FIG. 7C, wherein

$${t}_{k , j}^{+}$$

denotes the (k,j)th entry of

$${T}_{r e m}^{+} for 1 \leq k \leq t , 1 \leq j \leq N / 2$$

and t_{k,j} denotes the (k, j)th entry of Tᵣₑₘ for 1≤k≤t, 1≤j≤N. Step 7311 completes step 730 by returning Tᵣₑₘ.

Step 740 obtains a remedial set τᵣₑₘ from Tᵣₑₘ by computing the columns Sums

$${σ}_{k} = {\sum }_{k = 1}^{t} {( {T}_{r e m} )}_{k , j}$$

of Tᵣₑₘ for each 1≤j≤N, and setting τᵣₑₘ={j∈{1, 2, . . . , N}: σⱼ>0}. The elements of τᵣₑₘ indicate which elements of the transform output word x require remedial transmissions as part of Zᵣₑₘ.

Step 750 checks if the remedial set τᵣₑₘ is empty, and moves to step 760 or step 770 if the answer is YES or NO, respectively.

Step 760 outputs Zᵢₙᵢₜ as Z_{final}. It is worth noting that steps 710 through 760 constitute a method for checking if the pair (Φ, Zᵢₙᵢₜ) satisfies the zero-error constraints under SC decoding.

Step 770 obtains a remedial diversity code array Zᵣₑₘ from (Tᵣₑₘ, Tᵣₑₘ) by solving a node-cover problem for each element of τᵣₑₘ. For each j∈τᵣₑₘ, step 770 sets up an instance of the node-cover problem, represented by a bipartite graph Γⱼ. The bipartite graph Γⱼ is obtained from (τᵣₑₘ, Tᵣₑₘ) in the same manner as in step 670 of the ML-x method in FIG. 6A. Although the ML-x and SC-x methods use different methods to obtain their respective parameters (τᵣₑₘ, Tᵣₑₘ), once (τᵣₑₘ, Tᵣₑₘ) are obtained, the two methods use the same rules to construct Zᵣₑₘ.

Step 780 augments the initial diversity code array Zᵢₙᵢₜ with the remedial diversity code array Zᵣₑₘ to obtain a final diversity code array Z_{final}. Let C_{init,i} and C_{rem,i} denote the ith transmission sets of Zᵢₙᵢₜ and Zᵣₑₘ, respectively, for 1≤i>s. The final diversity code array Z_{final} is then defined such that its ith transmission set is given by C_{final,i}=C_{init,i} U C_{rem,i}, for 1≤i≤s. The pair (Φ, Z_{final}) is guaranteed to satisfy the zero-error constraints under SC decoding.

The formulas 73061, 73081, and 73101 are based on a recursive method of reducing a zero-error diversity code construction problem of size N to two problems of size N/2 using the Plotkin structure (u|u+v) of polar codes. The formulas 73101 are derived from the truth table 73102, which is designed by exhaustive analysis of the N=2 case. This completes the description of the SC-x method. We now turn to an example that demonstrates the SC-x method.

FIG. 7D illustrates an example 790 of the SC-x method of the flowchart 700 depicted in FIG. 7A. In example 790, step 710 identifies the input parameters (N, A, Φ, Zᵢₙᵢₜ) 791. Step 720 obtains the transform output word erasure array Q 792. Step 730 obtains the remedial array Tᵣₑₘ 793. Step 740 obtains the remedial set τᵣₑₘ 794. In example 790, step 750 determines that (Φ, Zᵢₙᵢₜ) does not satisfy the zero-error constraints under SC decoding, and proceeds to step 770. Step 770 obtains the remedial diversity code array Zᵣₑₘ 795. Step 780 combines the initial diversity code array Zᵢₙᵢₜ from 791 and the remedial diversity code array Zᵣₑₘ 795 to obtain the zero-error diversity code array Z_{final} 796. The SC-x method guarantees that the pair (Φ, Z_{final}) satisfies zero-error constraints under SC decoding. The code rate for Z_{final} is 11/22, which matches the benchmark code rate of 1/2.

Further details relating to the first level of recursion in step 730 of example 790 are as follows. Step 7306 obtains the pair (A⁻, Q⁻) 7931 using the formulas 73061. Step 7307 obtains the left remedial array

$${T}_{rem}^{-}$$

7932 by calling the method of step 730 with input (N/2, A⁻, Q⁻), wherein (A⁻, Q⁻) are as in 7931. Step 7308 obtains the pair (A⁺, Q⁺) 7933 using the formulas 73081. Step 7309 obtains the right remedial array

$${T}_{r e m}^{+}$$

7934 by calling the method of step 730 with input (N/2, A⁺, Q⁺), wherein (A⁺, Q⁺) are as in 7933. We omit illustration of calculations at further levels of recursion since they follow the same principles as shown here for the first level.

FIG. 8A is a flowchart 800 illustrating the steps of the SC-u method for constructing zero-error diversity codes in accordance with certain aspects of the present principles. The SC-u method takes as input a set of parameters (N, A, Φ, Zᵢₙᵢₜ) and produces a diversity code d→Z_{final} as output, where the pair (Φ, Z_{final}) is guaranteed to satisfy the zero-error constraints under a modified SC decoding. The details of each step of the SC-u method are provided below.

Step 810 identifies the input parameters (N, A, Φ, Zᵢₙᵢₜ), wherein N is a polar transform length, A is a data part index set, Φ is a zero-error constraints array, and d→Zᵢₙᵢₜ is an initial diversity code.

Step 820 obtains a transform output word erasure array Q=[q_{k,j}: 1≤k≤t, 1≤j≤N] from the parameters (N, Q, Zᵢₙᵢₜ) by setting q_{k,j} to 1 if j∈Bₖ, and to 0 otherwise, where B₁, B₂, . . . , Bₜ are the reception sets for the pair (Φ, Zᵢₙᵢₜ). Step 820 of the SC-u method is identical to step 720 of the SC-x method.

Step 830 obtains a transform input word erasure array R=[r_{k,j}: 1≤k≤t, 1≤j≤N] from (N, Q) by emulating an SC decoder under each zero-error constraint. For any (k, j)∈I_{R}, having r_{k,j}=1 indicates that, when the kth zero-error constraint is in effect, an SC decoder will experience an erasure in decoding uⱼ even if the entire initial segment (u₁, u₂, . . . , uⱼ₋₁) that precedes uⱼ in SC decoding order is frozen and known to the SC decoder. Thus, the non-zero entries of the array R indicate the problematic cases that require retransmission for constructing zero-error diversity codes.

Step 830 comprises steps 831-838 as illustrated in FIG. 8B, which involve calling step 830 recursively. Step 831 identifies the input parameters (N, Q). Step 832 checks the value of N and passes control to step 833 or step 834 depending on whether N=1 or N>1, respectively. Step 833 sets R=Q and proceeds to step 838. Step 834 obtains a left transform output word erasure array Q⁻ and a right transform output word erasure array Q⁺ by setting

$${q}_{k , j}^{-} = {q}_{k , j} ∨ {q}_{k , j + N / 2} and {q}_{k , j}^{+} = {q}_{k , j} ∧ {q}_{k , j + N / 2}$$

for 1≤k≤t and 1≤j≤N/2. Step 835 obtains a left transform input word erasure array R by a recursive call to step 830 using left-side input parameters (N/2, Q⁻). Step 836 obtains a right transform input word erasure array R⁺ by a recursive call to step 830 using right-side input parameters (N/2, Q⁺). Steps 835 and 836 can be executed in parallel. Step 837 obtains the transform input word erasure array R by setting R=[R⁻, R⁺] and passes control to step 838. More explicitly, step 837 sets

$${r}_{k , j} to {r}_{k , j}^{-} if 1 \leq k \leq t and 1 \leq j \leq N / 2 , and to {r}_{k , j - N / 2}^{+}$$

if 1≤k≤t and N/2+1≤j≤N. Step 838 returns R as the output of the current instance of the recursive procedure.

Step 840 obtains a remedial set τᵣₑₘ from R and A. Step 840 first computes the column sums

$${σ}_{j} = {\sum }_{k = 1}^{t} {r}_{k , j}$$

of R, for 1≤j≤N, and obtains the remedial set τᵣₑₘ={j∈{1, 2, . . . , N}: σⱼ>0}. The elements of τᵣₑₘ indicate which elements of the transform input word u require remedial transmissions on one or more subchannels to attain the goal of zero-error SC decoding.

Step 850 checks if the remedial set Tᵣₑₘ is empty, and proceeds to step 860 or step 870 if the answer is YES or NO, respectively.

Step 860 outputs Z_{final}=Zᵢₙᵢₜ as a zero-error diversity code array under SC decoding.

Step 870 obtains a remedial diversity code array Zᵣₑₘ from (τᵣₑₘ, R) by solving a node-cover problem for each element of τᵣₑₘ. The instance corresponding to j∈τᵣₑₘ is defined in terms of a bipartite graph Γⱼ consisting of a set of left-side nodes [symbol] ={k∈{1, 2, . . . , t}: r_{k,j}=1}, a set of right-side nodes [symbol] ={1, 2, . . . , s}, and edges (k, i) between a left-side node k∈ [symbol] and a right-side node i∈ [symbol] if and only if φ_{k,i}=1. Given a node-cover Hⱼ⊂ [symbol] step 870 constructs the remedial diversity code array Zᵣₑₘ as an array with s rows, where the ith row of Zᵣₑₘ contains the element u; if and only if j∈τᵣₑₘ and i∈Hⱼ, for 1≤j≤N and 1≤i≤s. Thus, the rows of Zᵣₑₘ comprise elements uⱼ with j∈τᵣₑₘ; each such element uⱼ appears in at least one row of Zᵣₑₘ; and, certain rows of Zᵣₑₘ may remain null.

Step 880 augments the initial diversity code array Zᵢₙᵢₜ with the remedial diversity code array Zᵣₑₘ to obtain a final diversity code array Z_{final}. Let C_{init,i} and C_{rem,i} denote the ith transmission sets of Zᵢₙᵢₜ and Zᵣₑₘ, respectively, for 1≤i≤s. The final diversity code array Z_{final} is then defined such that its ith transmission set is given by C_{final,i}=C_{init,i} U C_{rem,i}, for 1≤i≤s. The pair (Φ, Z_{final}) is guaranteed to satisfy the zero-error constraints under a modified form of SC decoding, which incorporates observations of elements of u into the decoding process.

We note that steps 810-850 of the flowchart 800 can be used as an “SC-check” method for checking if a given diversity code d→Zᵢₙᵢₜ is a zero-error diversity code under SC decoding. The SC-check and SC-u methods as presented here have complexity O(tN log₂ N), which shows that these methods can be implemented at low complexity for constructing zero-error diversity codes in real-time.

This completes the description of the SC-u method. We now turn to an example that demonstrates the SC-u method.

FIG. 8C illustrates an example 890 of the SC-u method depicted in FIG. 8A. In the example 890, step 810 identifies the input parameters (N, A, Φ, Zᵢₙᵢₜ) 891. Step 820 obtains the transform output word erasure array Q 892. Step 830 obtains the transform input word erasure array R 893. Step 840 obtains the remedial set as τᵣₑₘ 8931. Step 850 checks if τᵣₑₘ 8931 is empty and moves to step 870. Step 870 obtains the remedial diversity code array Zᵣₑₘ 894. Step 880 combines Zᵢₙᵢₜ from 891 and Zᵣₑₘ 894 to obtain a zero-error diversity code array Z_{final} 895. The code rate for Z_{final} 895 is 11/19, which is better than the benchmark code rate of 1/2.

The method depicted in flowchart 800 can be used to improve the code rate further by modifying the data part index set. The modified data part index set A′ is selected by minimizing the sum Σ_{k∈A}, σₖ over all sets A′⊂Iᵤ with a prescribed size |A′|=11. In example 890, this rule yields the alternative data part index set A′ 896. Method 800, with the input (N, A′, Φ, Zᵢₙᵢₜ), yields the remedial diversity code array

$${Z}_{r e m}^{′} 897$$

and the final diversity code array

$${Z}_{f i n a l}^{′} 898 .$$

the code rate for

$${Z}_{f i n a l}^{′}$$

898 is 11/18. This example demonstrates selecting the data part index set in accordance with the zero-error constraints Φ can improve the code rate of zero-error diversity codes.

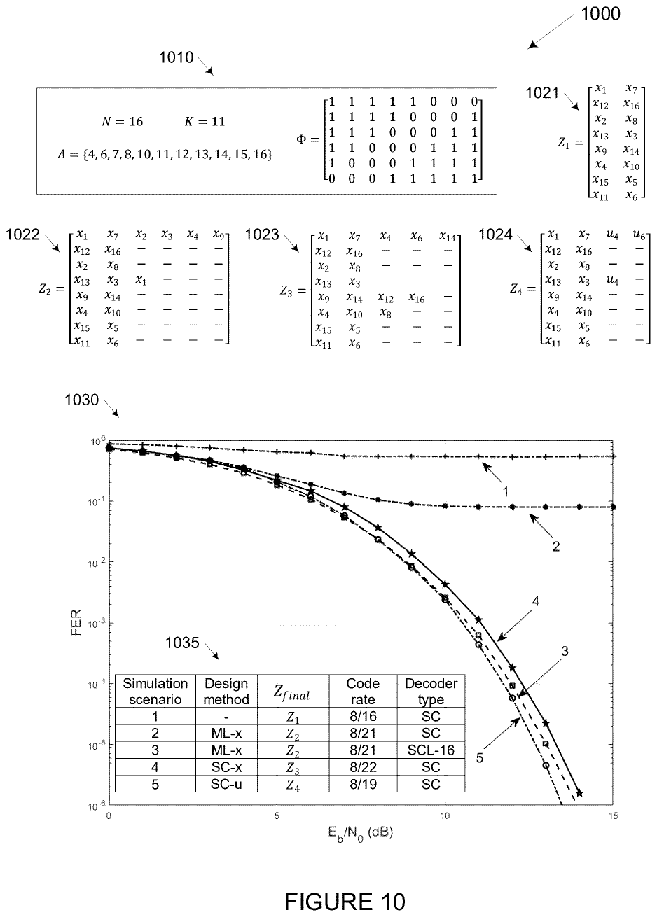

In general, the SC-u method enhances an initial design Zᵢₙᵢₜ by remedial transmissions chosen from the elements of the transform input word u. This process produces a final design Z_{final} such that (Φ, Z_{final}) satisfies the zero-error constraints under a slightly modified version SC decoding. This modified SC decoding incorporates observations of the transform input word u into the decoding process. One such modification from prior art is belief propagation (BP) decoding. By leveraging the flexibility of using elements of the transform input word u, the SC-u method may sometimes yield more efficient zero-error diversity code designs than ML-x and SC-x methods, as demonstrated by the examples shown in FIGS. 6B, 7B, and 8B. However, diversity code arrays constructed using the SC-u method may exhibit local weak spots-a topic discussed following the simulations presented in FIG. 10.

This completes the description of the encoder 320. The ML-x, SC-x, and SC-u methods for constructing zero-error diversity codes illustrate certain aspects of the present principles; however, they do not exhaust its full scope. These methods can be refined, combined with one another, or integrated with other known techniques-such as repetition—to develop alternative zero-error diversity code construction methods. All such methods fall within the scope of the present principles. Next, we turn our attention to the decoder 340.

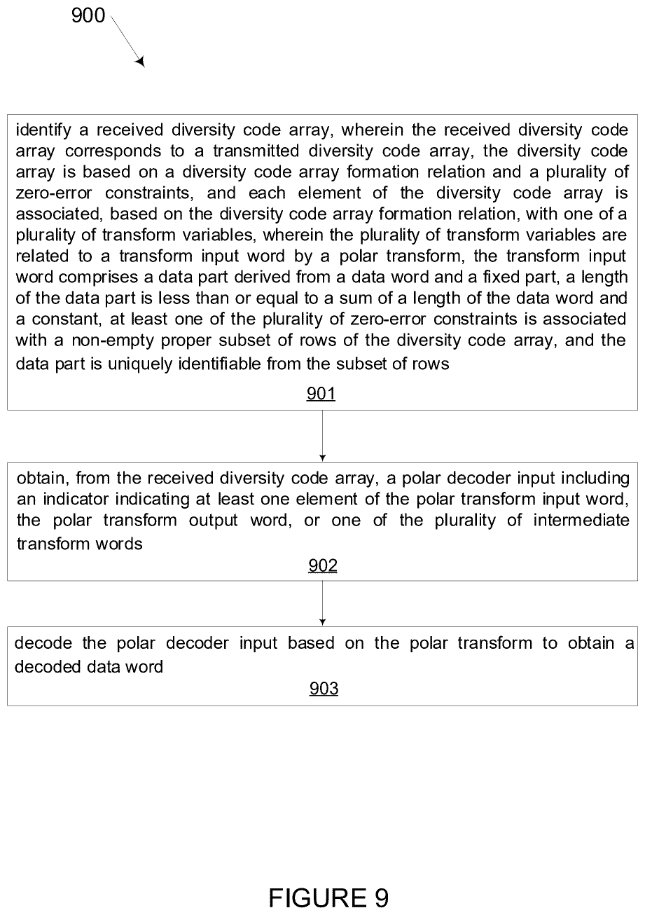

FIG. 9 is a flowchart illustrating a decoding method 900 in accordance with certain aspects the present disclosure. The decoding method 900 includes the steps of (901) identifying a received diversity code array, wherein the received diversity code array corresponds to a transmitted diversity code array, the diversity code array is based on a diversity code array formation relation and a plurality of zero-error constraints, and each element of the diversity code array is associated, based on the diversity code array formation relation, with one of a plurality of transform variables, wherein the plurality of transform variables are related to a transform input word by a polar transform, the transform input word comprises a data part derived from a data word and a fixed part, a length of the data part is less than or equal to a sum of a length of the data word and a constant, at least one of the plurality of zero-error constraints is associated with a non-empty proper subset of rows of the diversity code array, and the data part is uniquely identifiable from the subset of rows, (902) obtaining, from the received diversity code array, a polar decoder input including an indicator indicating at least one element of the polar transform input word, the polar transform output word, or one of the plurality of intermediate transform words, and (903) decoding the polar decoder input based on the polar transform to obtain a decoded data word. Steps 901 and 902 are executed at the diversity demapper 341 and step 903 is executed at the polar decoder 342.

The terms “received diversity code array” and “indicator,” mentioned in connection with FIG. 9, will be described by considering a preferred embodiment of the decoder 340. In the preferred embodiment of the decoder 340, the encoder 320 is assumed to transmit a diversity code array Z=[z_{i,j}: 1≤i≤s, 1≤j≤Mᵢ] over the channel 330. The channel 330, in turn, delivers to the decoder 340 a received diversity code array Y=[y_{i,j}: 1≤i≤s, 1≤j≤Mᵢ] of the same dimensions as Z. For each (i, j) in the index set I_{Z}=I_{Y}, the element z_{i,j} in the ith row of Z is transmitted over the ith subchannel and received at its output as y_{i,j}. The decoder is configured to operate in accordance with a model of the channel 330 characterized by channel transition probabilities W(Y|Z), where W(Y|Z) represents the likelihood of observing Y at the channel output given that Z is transmitted at the channel input. The decoder 340 assigns a state ψ=(ψ₁, ψ₂, . . . , ψₛ) to the channel 330, where ψᵢ represents the state of the ith subchannel 330-i, for 1≤i≤s. The decoder operates under channel transition probabilities of the form

$$W ( Y \vert Z , ψ ) = {\prod }_{i = 1}^{s} W ( {y}_{i} \vert {x}_{i} , {ψ}_{i} ) .$$

More specifically, the decoder 340 uses product-form channel transition probabilities

$$W ( Y \vert Z , ψ ) = {\prod }_{i = 1}^{s} {\prod }_{j = 1}^{{M}_{i}} W ( {y}_{i , j} \vert {z}_{i , j} , {ψ}_{i} ) ,$$

which corresponds to conditionally memoryless channel models given the channel state.

The diversity demapper 341 generates an indicator [symbol] for each element (k, [symbol] ) in the range of the mapping h: I_{Z}→Iₚ, which defines the array Z in terms of the elements of the FPT array P. To be specific, λ_{k,l} is assumed to be a likelihood ratio given by λ_{k,l}= [symbol] (0)/ [symbol] (1), where

$${γ}_{k , ℓ} ( α ) = {\sum }_{( i , j ) : h ( i , j ) = ( k , ℓ )} W ( {y}_{i , j} \vert {z}_{i , j} = α , {ψ}_{i} ) , α ∈ \{ 0 , 1 \} .$$

Here, [symbol] (α) is proportional to the conditional probability Pr(p_{k,l}=α|Y, ψ) of the event that the element p_{k,l} in the FPT array P equals α, given the received diversity code array Y and the channel state ψ. In other embodiments, λ_{k,l} may be a log-likelihood ratio, λ_{k,l}=log [ [symbol] (0)/ [symbol] (1)].

The diversity demapper 341 needs to compute the indicator [symbol] for those (k, [symbol] ) that are in the range of h. For instance, if the range of h comprises the elements of the transform output word x, then the diversity demapper computes [symbol] for x₁, x₂, . . . , x_{N}. If the range of h includes some elements of the data part of the transform input word u, then [symbol] is computed for those elements as well. The diversity demapper 341 makes the plurality of indicators { [symbol] : (k, [symbol] )∈range (h)} available to the polar decoder 342 as the polar decoder input.

The polar decoder 342 uses the plurality of indicators { [symbol] : (k, [symbol] )∈range (h)} to obtain a decoded data word \hat{d}=(\hat{d}₁, \hat{d}₂, . . . , \hat{d}_{K}). If these indicators comprise elements of the transform output word x, then a standard polar decoder—such as a successive cancellation (SC) decoder, a successive cancellation list (SCL) decoder, or a CRC-aided SCL decoder—may be used. However, if the indicators comprise elements of the FPT array other than x, then a version of polar decoding is required that can utilize the indicators corresponding to elements of the transform input word or internal transform words. A suitable decoder for this latter case is a belief-propagation (BP) decoder, which inherently supports this type of statistical likelihood processing. Other alternatives include appropriately modified SC or SCL decoders. This completes the description of the preferred embodiment of the decoder 340. This preferred embodiment is given solely for illustrative purposes and does not limit the scope of the present principles. One skilled in the art will have no difficulty in implementing the present principles using other embodiments of the decoder 340.

FIG. 10 presents a simulation-based comparison 1000 of the frame error rate (FER) performance of example diversity code arrays constructed in accordance with certain aspects of the present principles. The comparison 1000 demonstrates the practical benefits of the present principles. The example diversity code arrays in the comparison 1000 share a common set of parameters as shown in panel 1010. The polar transform size is N=16 and the length of the data word d is K=11. The data part index set A is chosen in accordance with the 5G NR polar code design rule. The polar encoder 321 prepares the transform input word by setting u_{A}=d and u_{A}_{^{c}}=0. The zero-error constraints are represented by the array Φ shown in panel 1010. Four diversity code arrays are compared: Z₁ 1021, Z₂ 1022, Z₃ 1023, and Z₄ 1024. The pair (Φ, Z₁) does not satisfy the zero-error constraints; it serves as a benchmark to illustrate the effectiveness of the present principles in improving FER performance. The other three codes, Z₂, Z₃, and Z₄, are zero-error diversity code arrays obtained from Z₁ by the ML-x, SC-x, and SC-u design methods, respectively. For further details on how these codes are constructed, we refer to FIGS. 6B, 7D, and 8C.

In the simulation setup, the channel 330 is simulated in accordance with the same model as discussed in connection with the preferred embodiment of the decoder 340. In other words, the channel 330 in the simulations is a channel with state w, derived from the rows of the zero-error constraints array Φ. Each row of Φ represents one possible state of the channel 330. Conditioned on the kth row φₖ being the active channel state, the channel transition probabilities are given by

$$W ( Y \vert Z , {ϕ}_{k} ) = {\prod }_{i = 1}^{s} {\prod }_{j = 1}^{{M}_{i}} p ( {y}_{i , j} \vert {z}_{i , j} , {ϕ}_{k , i} ) .$$

More specifically, we assume binary phase-shift keying (BPSK) modulation and an additive Gaussian channel. In this setup, the received signal is

$${y}_{i , j} = {ϕ}_{k , i} ( {ξ}_{i , j} + {w}_{i , j} )$$

where ξ_{i,j}=(−1)^{zi,j} is the BPSK signal at the input of the ith subchannel, and W_{i,j} is a zero-mean Gaussian noise variable with variance σ². The multiplicative term φ_{k,i} determines which subchannels are nullified under the zero-error constraint in effect. We assume that channel state information (CSI) is available at the decoder 340, meaning that the decoder can determine which zero-error constraint φₖ is active. Under these assumptions, the conditional channel probability density function, given the zero-error constraint φₖ, is

$$W ( {y}_{i , j} \vert {ξ}_{i , j} , {ϕ}_{k , i} ) = ( 1 - {ϕ}_{k , i} ) δ ( {y}_{i , j} ) + {ϕ}_{k , i} \frac{1}{\sqrt{2 π {σ}^{2}}} exp ( - \frac{{( {y}_{i , j} - {ξ}_{i , j} )}^{2}}{2 {σ}^{2}} ) ,$$

where δ(·) is the Dirac delta (impulse) function, corresponding to a unit probability mass at the origin-effectively erasing all the information sent over that subchannel—and becomes operative on subchannels i that are nullified by the kth constraint φₖ. Finally, to complete the model definition, each zero-error constraint is assumed to be equally likely, so each row φₖ of Φ is chosen with probability 1/t, where 1≤k≤t. Overall, this channel model corresponds to an additive white Gaussian noise (AWGN) channel with BPSK modulation and full CSI at the decoder.

In the present simulation setup, the diversity demapper 341 processes Y to obtain the plurality of indicators { [symbol] : (k, [symbol] )∈range (h)}, as discussed above in connection with the preferred embodiment of the decoder 340. The polar decoder 342 then decodes these likelihood indicators to obtain the decoded data word \hat{d}=(\hat{d}₁, \hat{d}₂, . . . , \hat{d}ₖ). A frame error is said to occur if \hat{d}≠d. The frame error rate (FER) is defined as the frequency of frame errors over a specified number of simulation runs or until a prescribed number of frame errors has occurred.

Chart 1030 presents results of the five simulation scenarios, as summarized in table 1035. Each curve in chart 1030 plots FER versus E_{b}/N₀ performance of one of the codes in table 1035. The parameter E_{b} is the energy per bit and N₀/2 is the double-sided noise power spectral density. In the BSPK-AWGN channel, E_{b}/N₀ equals

$$10 {log}_{10} ( \frac{1}{2 R {σ}^{2}} ) ,$$

where R is the code rate of the diversity code arrays under consideration. Since the diversity code arrays in chart 1030 have different code rates R, the parameter E_{b}/N₀ is used for a fair comparison. The right-most column of table 1035 indicates the type of decoder used in each simulation. For each simulation scenario, E_{b}/N₀ is varied from 0 dB to 15 dB in steps of 1 dB. At each Ep/N₀ value and for each zero-error constraint, we conduct 107 simulation runs and allow up to 200 frame errors. Once the measured FER, averaged over all zero-error constraints, drops below 10⁻⁶ at a given E_{b}/N₀, simulations at higher E_{b}/N₀ values are skipped. We provide specific details as we discuss each simulation scenario.

Performance curve 1 in chart 1030 illustrates that the diversity code array Z₁ 1021 experiences an error floor effect under SC decoding. This error floor cannot be eliminated by replacing the SC decoder with an ML decoder because there is not enough information at the channel output to uniquely identify the transmitted data word. Each zero-error constraint in Φ nullifies 6 elements of the array Z₁ 1021, leaving 10 elements intact, which is insufficient to recover the K=11 data bits.

Performance curve 2 in chart 1030 shows that the diversity code array Z₂ 1022, constructed by the ML-x method, also experiences an error floor under SC decoding. In this case, the error floor can be attributed to the suboptimality of the SC decoder, since the diversity code array Z₂ 1022 is, by construction, a zero-error diversity code array under ML decoding. This suggests using an SCL decoder.

Performance curve 3 in chart 1030 shows that the diversity code array Z₂ 1022 is free from an error floor effect when decoded by an SCL decoder with a list size of 16. This outcome is expected, as an SCL decoder's performance approaches that of an ML decoder as its list size grows. The second and third simulation scenarios thus demonstrate the practical utility of the ML-x construction method, even when an ML decoder cannot be employed in practice.

Performance curve 4 in chart 1030 shows that the diversity code array Z₃ 1023, constructed by the SC-x method, is free from an error floor under SC decoding.

Performance curve 5 in chart 1030 indicates that the diversity code array Z₄ 1024, constructed by the SC-u method, exhibits no error floor under SC decoding, as expected. It should be noted that the SC decoder used here is a modified version, capable of incorporating the direct observations of the elements u₄ and u₆ in its decoding process.

Simulation results highlight the practical utility and effectiveness of the present principles. Of the five scenarios presented in FIG. 10, the diversity code array Z₄ 1024, constructed using the SC-u method, achieves the best performance. However, drawing broad conclusions about the relative strengths of the ML-x, SC-x, and SC-u methods based solely on this small-scale study would be premature. Diversity codes arrays constructed by the SC-u method may be susceptible to single-bit transmission errors.

For example, if the bit u₆ in the diversity code array Z₄ 1024 is received incorrectly due to additive noise, it could lead to the entire frame being decoded incorrectly. However, local weak spots in a diversity code array generated by the SC-u method can often be mitigated at low cost through repetition. For instance, the weak spot u₆ in the first row of Z₄ can be strengthened by modifying the first row to [x₁, x₇, u₄, U₆, U₆], so that repeated transmission of u₆ increases the probability of correct decoding. Importantly, such repetition techniques can be applied to any zero-error diversity code array construction method. The scope of the present principles encompasses all such modifications and extensions to the specific zero-error diversity code array construction methods described herein.

The description concludes with additional remarks on a various implementation alternatives, in particular implementation under backward compatibility constraints.

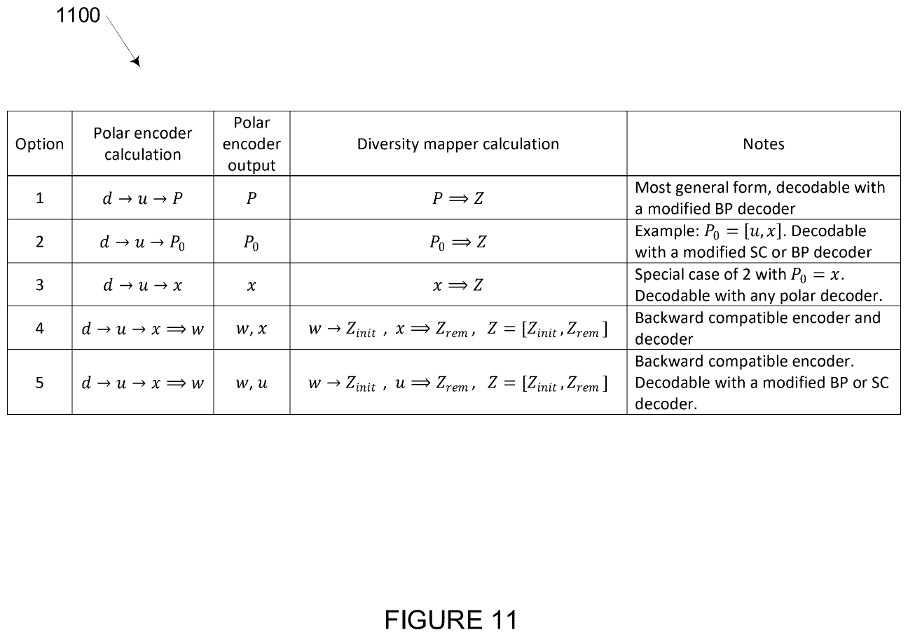

FIG. 11 is a table 1100 that presents five implementation options for the encoder 320 in accordance with certain aspects of the present principles. The table presents different configurations based on the internal calculation stages at the polar encoder 321 and the diversity mapper 322. Each row of the table corresponds to a different implementation option, detailing the flow from input through internal processing to the final output.

In table 1100, some operations between arrays or words are indicated by arrows of type “→”. The notation “a→b” denotes an invertible functional relationship, meaning there exists a function g: A→B with domain A and range B, such that a∈A, b∈B, and b=g(a), where α is uniquely determined by b. For example d→u is justified since u is derived from d by an invertible functional relationship, which we refer to as the transform input word formation relation. Similarly, the notations u→P and u→x are justified, as both x and P are obtained from u through an invertible polar transform operation.

Some other operations in table 1100 are indicated by arrows of type “⇒”. The notation “a⇒b” represents the operation of copying elements from array a into array b, allowing for omissions and repetitions. For example, “x⇒w” means that the polar code word w is derived from the transform output word x by a copy operation, where some elements of x may be omitted, while others may be repeated. Similarly, P⇒Z indicates that the diversity code array Z is obtained from the FPT array P through a copy operation of the same type, where elements of P may be omitted or copied multiple times. The copy operation “a⇒b” is governed by a function that associates each element of b with some element of a. Each element of α is copied into b as many times as it appears in the range of this function. The governing function in the case of the copy operation “P⇒Z” is referred to as the “diversity code array formation relationship.”

In option 1, the polar encoder 321 calculates the entire FPT array P from the transform input word u and makes the array P available to the diversity mapper 322. This represents the most general form of the present principles, offering the diversity mapper maximum flexibility in the formation of the diversity code array. However, this option is also the most resource-intensive, as the entire FPT array must be stored and made accessible to the diversity mapper. Additionally, this option requires a specialized decoder that can incorporate observations of arbitrary elements from the FPT array into the decoding process. The most suitable type of decoder for this purpose is the belief propagation (BP) decoder.

In option 2, the polar encoder 321 calculates a predefined subarray P₀ of the FPT array P from the transform input word u and makes the array P₀ available to the diversity mapper 322. For example, P₀ may include the transform input word u and the transform output word x. The ML-x, SC-x, or SC-u methods can be used as part of this option for constructing a zero-error diversity code array. Compared to option 1, this option is much less resource intensive. Option 2 requires a minor modification to an SC, SCL, or BP decoder to incorporate the observations of the transform input word u into the decoding process.

In option 3, the polar encoder 321 calculates the transform output word x from the transform input word u and makes x available to the diversity mapper 322. The ML-x or SC-x methods can be employed as part of this option for constructing a zero-error diversity code array. Option 3 is compatible with standard polar decoders in prior art.

In option 4, the polar encoder 321 calculates the transform output word x from the transform input word u, obtains a polar code word w from x through a copy operation x⇒W, and makes both x and w available to the diversity mapper 322. Instead of constructing the diversity code array Z directly from the combination of x and w (which would result in a scenario similar to option 3), the diversity mapper in option 4 first obtains an initial diversity code array Zᵢₙᵢₜ via an invertible functional relation w→Zᵢₙᵢₜ, and a remedial diversity code array Zᵣₑₘ via the copy operation x⇒Zᵣₑₘ. A zero-error diversity code array Z is then obtained by combining Zᵢₙᵢₜ and Zᵣₑₘ in a predefined manner. The ML-x and SC-x examples shown in FIGS. 6 and 7 illustrate zero-error diversity code construction using this option. Option 4 is compatible with prior art polar encoders and decoders, such as those for 5G NR polar codes.

In option 5, the polar encoder 321 calculates the transform output word x from the transform input word u, obtains a polar code word w from x through a copy operation x⇒W, and makes the transform input word u (or just the data part of u) and the polar code word w available to the diversity mapper 322. The diversity mapper in option 5 first obtains an initial diversity code array Zᵢₙᵢₜ via an invertible functional relation w→Zᵢₙᵢₜ, and a remedial diversity code array Zᵣₑₘ via the copy operation u⇒Zᵣₑₘ. A zero-error diversity code array Z is then obtained by combining Zᵢₙᵢₜ and Zᵣₑₘ in a predefined manner. The SC-u example shown in FIG. 8 illustrates zero-error diversity code construction using this option. Option 5 requires a minor modification to an SC, SCL, or BP decoder, similar to option 2.

The five implementation options described above are by no means exhaustive. They are provided to illustrate some sample implementations of the present principles. In reality, many other implementation options are possible. The scope of the present principles covers all such implementations, and the person skilled in the art will have no difficulty identifying and implementing these variations based on the disclosed principles.

While the particular METHODS AND APPARATUS FOR ERROR CORRECTION CODING WITH TRANSMISSION DIVERSITY is herein described in detail and is depicted in the drawings, it is to be understood that the subject matter which is encompassed by the present disclosure is limited by the claims. Although the present disclosure has been described with exemplary embodiments, various changes and modifications may be suggested to one skilled in the art. It is intended that the present disclosure encompass such changes and modifications that fall within the scope of the appended claims. The description in the present application should not be read as implying that any particular element, step, or function is an essential or critical element which must be included in the claim scope: the scope of patented subject matter is defined by the allowed claims. Moreover, none of these claims are intended to invoke 35 USC § 112 (f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112 (f).

Although the present disclosure has been described with various embodiments, various changes and modifications may be suggested to one skilled in the art. It is intended that the present disclosure encompass such changes and modifications as fall within the scope of the appended claims.

What is claimed is:

1. An encoder apparatus in a communication system, the encoder apparatus comprising:
a polar encoder configured to:
identify a data word,
obtain a transform input word comprising a data part derived from the data word and a fixed part, wherein a length of the data part is less than or equal to a sum of a length of the data word and a constant, and
obtain a plurality of transform variables from the transform input word based on a polar transform, and
a diversity mapper configured to:
generate a diversity code array based on a diversity code array formation relation and a plurality of zero-error constraints, wherein, based on the diversity code array formation relation, an element of the diversity code array is associated with one of the plurality of transform variables, wherein at least one of the plurality of zero-error constraints is associated with a non-empty proper subset of rows of the diversity code array and the data part is uniquely identifiable from the subset of rows, and
transmit the diversity code array.

2. The encoder apparatus of claim 1, wherein the plurality of transform variables comprises a transform output word and each element of the diversity code array is associated with an element of the transform output word.

3. The encoder apparatus of claim 1, wherein the plurality of transform variables comprises an element of the transform input word and at least one element of the diversity code array is associated with an element of the transform input word.

4. The encoder apparatus of claim 1, wherein the polar encoder is further configured to obtain a polar code word from the plurality of transform variables according to a polar code word formation relation, wherein the diversity code array comprises an initial part and a remedial part and each element of the initial part is associated with an element of the polar code word.

5. The encoder apparatus of claim 1, wherein each row of the diversity code array is associated with a subchannel in a channel according to a subchannel assignment relation, and the diversity mapper is configured to transmit the rows of the diversity code array over the associated subchannels.

6. The encoder apparatus of claim 1, wherein the plurality of zero-error constraints is dynamically determined based on a channel state information.

7. The encoder apparatus of claim 1, wherein, for each zero-error constraint, the data part is uniquely identifiable under successive cancellation decoding from the subset of rows under successive cancellation decoding.

8. The encoder apparatus of claim 1, wherein the data part of the transform input word is identified by a data part index set, determined, in part, based on the plurality of zero-error constraints.

9. The encoder apparatus of claim 1, wherein a product of a length of the data word and a transversal number of the plurality of zero-error constraints is less than a total number of elements in the diversity code array.

10. The encoder apparatus of claim 1, wherein each of the plurality of zero-error constraints is associated with a distinct subset of rows of the diversity code array such that the data part is uniquely identifiable from each of the distinct subset of rows.

11. A decoder apparatus in a communication system, the decoder apparatus comprising:
a diversity demapper configured to:
identify a received diversity code array, wherein the received diversity code array corresponds to a transmitted diversity code array, the transmitted diversity code array is based on a diversity code array formation relation and a plurality of zero-error constraints, and each element of the transmitted diversity code array is associated, based on the diversity code array formation relation, with one of a plurality of transform variables, wherein the plurality of transform variables are related to a transform input word by a polar transform, the transform input word comprises a data part derived from a data word and a fixed part, a length of the data part is less than or equal to a sum of a length of the data word and a constant, at least one of the plurality of zero-error constraints is associated with a non-empty proper subset of rows of the transmitted diversity code array, and the data part is uniquely identifiable from the subset of rows, and
obtain, from the received diversity code array, a polar decoder input including an indicator indicating at least one element of the plurality of transform variables,
a polar decoder configured to:
decode the polar decoder input based on the polar transform to obtain a decoded data word.

12. The decoder apparatus of claim 11, wherein the plurality of zero-error constraints is dynamically determined based on a channel state information.

13. The decoder apparatus of claim 11, wherein the data part of the transform input word is identified by a data part index set, determined, in part, based on the plurality of zero-error constraints.

14. The decoder apparatus of claim 11, wherein a product of a length of the data word and a transversal number of the plurality of zero-error constraints is less than a total number of elements in the transmitted diversity code array.

15. The decoder apparatus of claim 11, wherein each of the plurality of zero-error constraints is associated with a distinct subset of rows of the transmitted diversity code array such that the data part is uniquely identifiable from each of the distinct subset of rows.

16. An encoding method in a communication system, the encoding method comprising:
a polar encoding step, wherein the polar encoding step comprises:
identifying a data word,
obtaining a transform input word comprising a data part derived from the data word and a fixed part, wherein a length of the data part is less than or equal to a sum of a length of the data word and a constant, and
obtaining a plurality of transform variables from the transform input word based on a polar transform, and
a diversity mapping step, wherein the diversity mapping step comprises:
generating a diversity code array based on a diversity code array formation relation and a plurality of zero-error constraints, wherein, based on the diversity code array formation relation, an element of the diversity code array is associated with one of the plurality of transform variables, wherein at least one of the plurality of zero-error constraints is associated with a non-empty proper subset of rows of the diversity code array and the data part is uniquely identifiable from the subset of rows, and
transmitting the diversity code array.

17. The encoding method of claim 16, wherein the polar encoding step further comprises obtaining a polar code word from the plurality of transform variables according to a polar code word formation relation, wherein the diversity code array comprises an initial part and a remedial part and each element of the initial part is associated with an element of the polar code word.

18. The encoder method of claim 16, wherein the plurality of zero-error constraints is dynamically determined based on a channel condition.

19. The encoding method of claim 16, wherein each of the plurality of zero-error constraints is associated with a distinct subset of rows of the diversity code array such that the data part is uniquely identifiable from each of the distinct subset of rows.

20. A decoding method in a communication system, the decoding method comprising:
a diversity demapping step, wherein the diversity demapping step comprises:
identifying a received diversity code array, wherein the received diversity code array corresponds to a transmitted diversity code array, the transmitted diversity code array is based on a diversity code array formation relation and a plurality of zero-error constraints, and each element of the transmitted diversity code array is associated, based on the diversity code array formation relation, with one of a plurality of transform variables, wherein the plurality of transform variables are related to a transform input word by a polar transform, the transform input word comprises a data part derived from a data word and a fixed part, a length of the data part is less than or equal to a sum of a length of the data word and a constant, at least one of the plurality of zero-error constraints is associated with a non-empty proper subset of rows of the diversity code array, and the data part is uniquely identifiable from the subset of rows, and
obtaining, from the received diversity code array, a polar decoder input including an indicator indicating at least one element of the plurality of transform variables,
a polar decoding step, wherein the polar decoding step comprises:
decoding the polar decoder input based on the polar transform to obtain a decoded data word.

21. The decoding method of claim 20, wherein the plurality of zero-error constraints is dynamically determined based on a channel condition.

22. The decoding method of claim 20, wherein each of the plurality of zero-error constraints is associated with a distinct subset of rows of the transmitted diversity code array such that the data part is uniquely identifiable from each of the distinct subset of rows.
